(19) United States
(12) Patent Application Publication
(10) Pub. No.: US 2026/0113912 A1
(43) Pub. Date: Apr. 23, 2026

(54) SYSTEMS AND METHODS FOR COOLING AN ELECTRONICS HOUSING

(71) Applicant: Rivian IP Holdings, LLC, Irvine, CA (US)

(72) Inventors: Xingyu Ren, Irvine, CA (US); Tapan Shirish Mhatre, Cerritos, CA (US); Nicholas Athol Keeling, Irvine, CA (US); Sanchita Sheth, San Jose, CA (US); Heng Kang, Los Angeles, CA (US)

(21) Appl. No.: 19/189,579

(22) Filed: Apr. 25, 2025

Related U.S. Application Data
(60) Provisional application No. 63/708,533, filed on Oct. 17, 2024.

(51) Int. Cl. H05K 7/20; B60L 53/22; H05K 7/14

(52) U.S. Cl. CPC H05K 7/20909; H05K 7/1432; B60L 53/22; B60L 2240/36

(57) ABSTRACT

An apparatus includes a first opening in the body configured to move air into the cavity and a second opening in the body configured to move air out of the cavity. A first heat dissipating structure is coupled to a first region of the body. The first heat dissipating structure is configured to remove a first amount of heat. A first electronic component is coupled to a first interior surface of the cavity. The first interior surface corresponds to the first region. A first heat flow path is formed from the first electronic component, through the first interior surface and the first region, and to the first heat dissipating structure. A second heat dissipating structure is coupled to a second region of the body. The second heat dissipating structure is configured to remove a second amount of heat.

### CROSS-REFERENCE TO RELATED APPLICATION

This Patent Application claims priority to U.S. Provisional Patent Application No. 63/708,533, filed on Oct. 17, 2024, and entitled “Bidirectional Charging Systems and Methods.” The disclosure of the prior Application is considered part of and is incorporated by reference into this Patent Application.

### INTRODUCTION

The present disclosure is directed to systems and methods for a vehicle charging system, and more particularly to systems and methods for bi-directional charging of a vehicle.

### SUMMARY

A vehicle charging system may provide power to a vehicle, such as to charge a battery of the vehicle. The power may be received from a power source, such as an electrical grid that distributes power from a power company, and may also be used to power an external system, such as a home. Different power support scenarios may affect operation of the vehicle charging system. Some power companies may have electricity rates that vary by a time of day and/or a day of the week. Energy arbitrage techniques may be used to offset the variable rates. For example, it may be cheaper to charge a battery of the vehicle at night (e.g., when rates may be cheaper) and, if possible, use power from the battery of the vehicle during the day (e.g., when rates may be more expensive) instead of the electrical grid. Some power companies receive grid support from their customers. A customer may provide power that is generated on their property, or otherwise available on-site, to the electrical grid to support grid energy usage. When power from the electrical grid is down, the vehicle and the home may no longer receive power. The vehicle charging system and devices that are powered through the home may remain offline or unusable until power to the grid is restored, which may require several days. An auxiliary power system, such as a backup generator, may be used to provide power in such scenarios. However, auxiliary power systems may require any one or combination of additional equipment that can be costly to install and maintain, equipment that is noisy when in operation, modification to a home's existing electrical infrastructure, or additional space for the equipment's footprint. Thus, a means for enabling bi-directional power flow between a vehicle and other systems and/or sources that accommodates different power support scenarios is needed.

In one approach, a system for managing power flow is provided. The system may have cooling requirements that affect the system's size or footprint. Cooling systems, such as external heat sinks or liquid cooling systems, may be used to remove heat generated by the system. While this approach may satisfy cooling requirements, it may add bulk to the system and/or require maintenance of another system.

In another approach, wireless communication with the system may be affected by a material or layout of components of the system. The components may attenuate, degrade, or block wireless signals from reaching the system. Wireless communication may be affected by a surrounding environment. The environment may be indoors or in a home, where walls or other material may attenuate, degrade, or block the wireless signals. Since communication with the system may not be consistent, the system may not provide reliable management of power flow.

In another approach, the system may be difficult to service or maintain. Specialized tooling may be required to access or remove components of the system, which may require additional inventory and cost. Components that do not need to be serviced may need to be removed to access components that require servicing. The entire system or subsystem may need to be removed and/or replaced to when servicing. Although the system may be serviced, the servicing may result in the system being unavailable for an undesirable amount of time. If components cannot be accessed on site, then replacement of the system may be required.

Accordingly, there is a need to provide a system for enabling bi-directional power flow that satisfies cooling requirements while accounting for maintenance costs and footprint constraints, provides consistent wireless communication, and may be serviced on-site, such as at a residential location.

To help address these problems, systems and methods are provided herein for addressing cooling requirements of a system for managing power flow. The system may include an apparatus having a dual-purpose housing that functions as a structural chassis and a heat dissipating structure. The housing may provide a heat flow path that removes heat generated by electronic components of the system. Various airflow generating devices may be used to encourage airflow around the electronic components, move hotter air away from the electronic components, or move heat dissipated by the housing away from the system. Thus, the dual-purpose housing and airflow generating device configuration may require less maintenance than external heat sinks or liquid cooling systems. The dual-purpose housing system and compact airflow generating device arrangement may provide a system having a smaller size than a system that uses the external heat sinks or liquid cooling systems.

In some embodiments, an apparatus comprises a first opening in the body configured to move air into the cavity and a second opening in the body configured to move air out of the cavity. The apparatus further comprises a first heat dissipating structure coupled to a first region of the body. The first heat dissipating structure is configured to remove a first amount of heat. The apparatus further comprises a first electronic component coupled to a first interior surface of the cavity. The first interior surface corresponds to the first region. A first heat flow path is formed from the first electronic component, through the first interior surface and the first region, and to the first heat dissipating structure. The apparatus further comprises a second heat dissipating structure coupled to a second region of the body. The second heat dissipating structure is configured to remove a second amount of heat.

In some embodiments, an apparatus comprises a body forming a cavity. The body comprises a plurality of openings in the body configured to move air through the cavity. The apparatus further comprises first cooling fins coupled to a first region of the body. Each fin of the first cooling fins extending a first height from the first region. The apparatus further comprises second cooling fins coupled to a second region of the body. Each fin of the second cooling fins extending a second height from the second region. The apparatus further comprises an airflow generating venting device coupled to an opening of the plurality of openings configured to move air out of the opening. The apparatus further comprises an airflow generating stir device arranged in the cavity and configured to move air in the cavity.

In some embodiments, a method comprises coupling a first electronic component to a first interior surface within a cavity of a housing. The housing comprises a first heat dissipating structure coupled to a first exterior surface of the housing. The first heat dissipating structure is configured to remove a first amount of heat. The housing further comprises a second heat dissipating structure coupled to a second exterior surface of the housing. The second heat dissipating structure is configured to remove a second amount of heat. The first interior surface is opposite the first exterior surface of the housing. The method further comprises coupling a second electronic component to a second interior surface within the cavity of the housing. The second interior surface is opposite the second exterior surface of the housing.

### BRIEF DESCRIPTION OF THE DRAWINGS

The present disclosure, in accordance with one or more various embodiments, is described in detail with reference to the following figures. The drawings are provided for purposes of illustration only and merely depict typical or example embodiments. These drawings are provided to facilitate an understanding of the concepts disclosed herein and should not be considered limiting of the breadth, scope, or applicability of these concepts. It should be noted that for clarity and ease of illustration, these drawings are not necessarily made to scale.

FIG. 1 is a schematic illustration of a power management system, in accordance with embodiments of the disclosure;

FIG. 2 is an exploded illustration of a bi-directional charger, in accordance with embodiments of the disclosure;

FIG. 3A is a schematic illustration of an electronics housing, in accordance with embodiments of the disclosure;

FIG. 3B is a schematic offset section cutaway illustration of the electronics housing in FIG. 3A, in accordance with embodiments of the disclosure;

FIGS. 4A and 4B are schematic illustrations of an electronics housing, in accordance with embodiments of the disclosure;

FIG. 5 is a flowchart of an illustrative process for installing electronic components in an electronics housing, in accordance with embodiments of the disclosure;

FIGS. 6A and 6B are schematic illustrations of an arrangement of components of antenna system of a bi-directional charger, in accordance with embodiments of the disclosure;

FIGS. 7A and 7B are schematic illustrations of an antenna system of a bi-directional charger, in accordance with embodiments of the disclosure;

FIG. 8 is a flowchart of an illustrative process for installing an antenna system in a bi-directional charger, in accordance with embodiments of the disclosure;

FIG. 9 is a schematic illustration of components within an enclosure of a bi-directional charger, in accordance with embodiments of the disclosure;

FIG. 10 is a schematic illustration of an enclosure of a bi-directional charger enclosure, in accordance with embodiments of the disclosure;

FIG. 11 is a schematic illustration of a mounting system for a bi-directional charger, in accordance with some embodiments of this disclosure; and

FIG. 12 is a flowchart of an illustrative process for servicing components of a bi-directional charger, in accordance with embodiments of the disclosure.

### DETAILED DESCRIPTION

A vehicle charging system is provided that includes systems, components, and/or assemblies that enable bi-directional (BiDi) power flow between a vehicle, a power source, and/or an external system. In one approach, the vehicle charging system includes a BiDi charger that includes any of an enclosure and component layout that increases serviceability, an electronics housing having dual purpose functionality as a structural chassis for the BiDi charger and a cooling system for the BiDi charger, an antenna system, and a mounting system. Such features may improve serviceability and reduce a size or footprint of the vehicle charging system as discussed below.

In one approach, the vehicle charging system enables home backup power by enabling power to flow from a vehicle to an external system. In some embodiments, the external system includes any one or combination of a building and associated electrical infrastructure, a branch circuit, an appliance, heating and/or cooling systems, electrical devices (e.g., phone, computer, modem, router, television, gaming console, etc.), lighting, another vehicle, a main panel, a subpanel, a breaker box, or an electrical grid, to name a few examples.

In some embodiments, a BiDi thermal architecture is presented. An exterior of the electronics enclosure has heat dissipating sections. A cavity of the electronics housing may contain any one or combination of electronic components that are sensitive to handling or a surrounding environment, high-voltage electronic components, high-tolerance electronic components, electronic components having a high-tolerance interface, or electronic components that are not accessed on-site for maintenance or field repairs. Each of the electronic components, or subsets of the electronic components, may generate different amounts of heat and have different cooling requirements. The electronics system may include several items that form a cooling system for the BiDi charger. The electronics housing may include different heat dissipating sections that are thermally coupled to the electronic components. Each of the heat dissipating sections may accommodate the various cooling requirements of electronic components that are thermally coupled thereto. The heat dissipating sections may include heat dissipating structures that increase an area of the heat dissipating sections that is available for heat transfer. In some embodiments, an internal airflow generating stir device moves air around the cavity to promote heat transfer. In some embodiments, an airflow generating venting device moves outside air through the cavity and out a vent opening to remove heat from within the cavity. In some embodiments, an external airflow generating assembly moves air over a surface of the heat dissipating sections to remove heat. The dual-purpose functionality of the electronics enclosure may reduce complexity, size, weight, or manufacturing costs when compared to conventional charger systems, which may use bulky external heat sinks or a separate or standalone liquid cooling system. The thermal architecture of the electronics enclosure may increase reliability by reducing components or optimizing thermal pathways for heat removal. The thermal architecture of the electronics enclosure may increase a useable lifespan of electronics of the electronics enclosure by reducing operating temperatures.

In some embodiments, an architecture for a BiDi antenna system is presented. The electronics housing may not allow signals to reliably travel through. A first antenna and a second antenna may be positioned at different locations inside the enclosure to ensure coverage from in front of the system and behind the system. For example, if the first antenna is positioned adjacent to a front of the electronics housing, the first antenna may not receive signals from behind the system. The second antenna may be placed adjacent to a side of the electronics housing, which may be perpendicular to the front, to remediate this “dead zone” in coverage. The second antenna may receive signals from behind the housing, and in some instances, from in front of the system too. A backplate of the enclosure may include a cutout adjacent to the second antenna to facilitate reception of the signals from behind the housing.

In some embodiments, a BiDi enclosure packaging configuration is presented. The enclosure restricts access to components arranged within, which prevent a technician or user from accessing high-voltage components. Systems and components within the enclosure are laid out in a manner that allows easier access to field serviceable components and hinders access to non-field serviceable components. The field serviceable components may be easily removed from the enclosure or grouped in a service area housing that can be accessed using standard tools or hardware. The non-field serviceable components may be contained within the electronics housing, which may be coupled to the backplate of the enclosure and not easily removed or opened with standard tools or hardware.

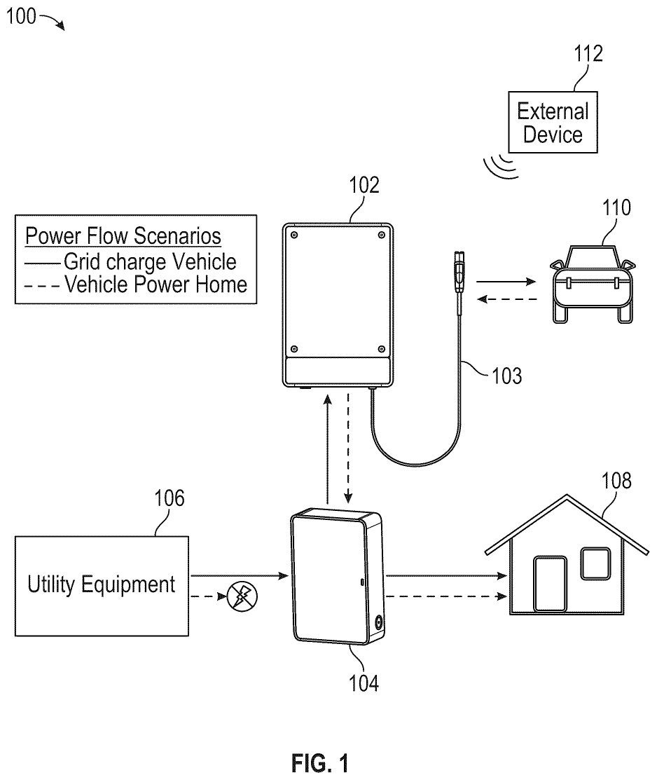

FIG. 1 is a schematic illustration of a power management system 100, in accordance with embodiments of the disclosure.

In some embodiments, the power management system 100 includes a BiDi charger 102 and an automatic grid disconnect (AGD) 104. In some embodiments, the AGD 104 is electrically coupled to any one or combination of utility equipment 106, an electrical infrastructure 108, or the BiDi charger 102. The BiDi charger 102 may be electrically coupled to a vehicle 110. In some embodiments, the BiDi charger 102 includes a charging cable 103 that may be physically and/or electrically coupled to a vehicle 110 to provide power to the vehicle 110. In some embodiments, an external device 112 communicates with any one or combination of the BiDi charger 102, the AGD 104, the utility equipment 106, the electrical infrastructure 108, or the vehicle 110. In some embodiments, the external device 112 includes any one or combination of a smartphone, a desktop and/or laptop computer, a television, a smart appliance, a smart doorbell, a security system, a power and/or energy monitoring system, a server, or any other device that may communicate with the BiDi charger 102, the AGD 104, the utility equipment 106, the electrical infrastructure 108, or the vehicle 110.

In some embodiments, the utility equipment 106 includes a power input from an electrical grid. In some implementations, the utility equipment 106 includes any one or combination or an electric meter, a service panel, a service drop, a service lateral, or a transformer. In some embodiments, the utility equipment 106 includes a battery or backup battery. In some embodiments, the utility equipment 106 includes any one or combination of a generator, solar power system, wind power system, or other power system, to name a few examples. In some embodiments, the electrical infrastructure 108 includes an electrical system that distributes power for a building, such as a home, plant, facility, or office, to name a few examples. In some embodiments, the electrical infrastructure 108 includes any one or combination of a main panel, circuit breaker, branch circuit, or electrical outlets, to name a few examples.

In some embodiments, the BiDi charger 102 is electrically coupled to a battery or power generating system of the vehicle 110. In some embodiments, the vehicle 110 is an electric vehicle having a battery. In some embodiments, the vehicle 110 includes an internal combustion engine (e.g., gasoline, diesel, hydrogen, etc.) having a battery and/or alternator.

In some embodiments, the AGD 104 enables BiDi power transfer to/from the BiDi charger 102. In some implementations, the AGD 104 provides power to the vehicle 110 (e.g., from the utility equipment 106). In some implementations, the AGD 104 provides power to the electrical infrastructure 108 (e.g., from the vehicle 110 and/or the utility equipment 106). The embodiment depicted in FIG. 1 includes two power flow scenarios. In a first scenario, the AGD 104 distributes power input from the utility equipment 106 to the BiDi charger 102 and the electrical infrastructure 108. The BiDi charger 102 distributes power to the vehicle 110. In a second scenario, there is no power input from the utility equipment 106. The AGD 104 distributes power from the BiDi charger 102 to the electrical infrastructure 108. The BiDi charger 102 receives power from the vehicle 110.

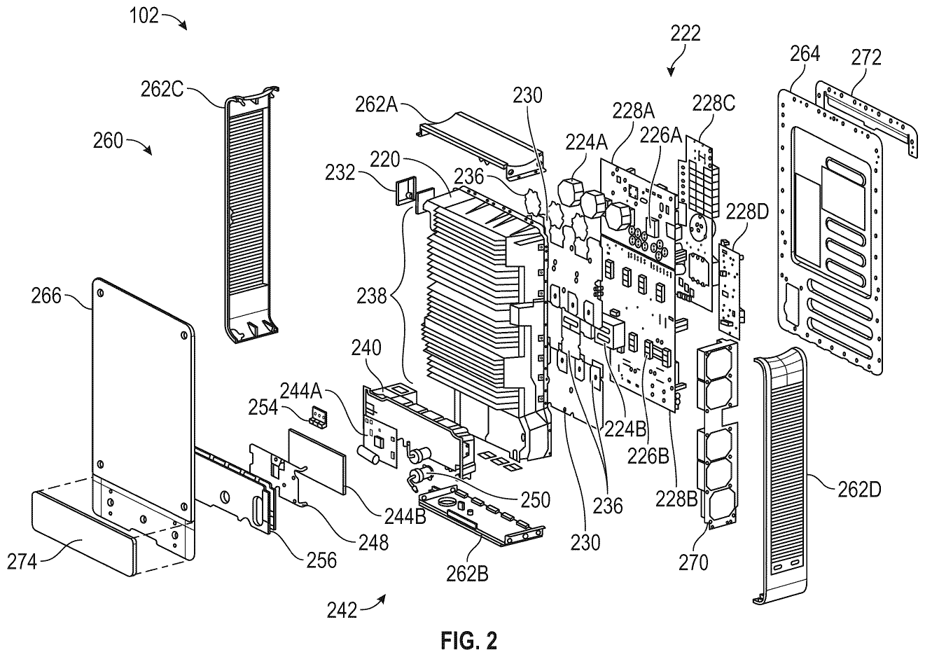

FIG. 2 is an exploded illustration of the BiDi charger 102, in accordance with embodiments of the disclosure.

The BiDi charger 102 may be used to accommodate different power support scenarios. In some embodiments, the BiDi charger 102 enables energy arbitrage techniques. In some implementations, the BiDi charger 102 charges a battery of a vehicle (e.g., the vehicle 110 in FIG. 1) during a first time period (e.g., when rates are cheaper) and uses the battery to power an external system (e.g., the electrical infrastructure 108 in FIG. 1) during a second time period (e.g., when rates are more expensive). In some embodiments, the BiDi system 102 provides grid support. In some implementations, the BiDi system 102 provides power to utility equipment (e.g., the utility equipment 106 in FIG. 1). In some embodiments, the BiDi charger 102 reduces or eliminates power disruptions associated with conventional power supply methods for electrical infrastructure (e.g., the electrical infrastructure 108 in FIG. 1). For example, the BiDi charger 102 may be used to provide power from the vehicle to the electrical infrastructure. As shown, the BiDi charger 102 includes an electronics housing 220, service area housing 240, an external airflow generating device 270, and enclosure 260.

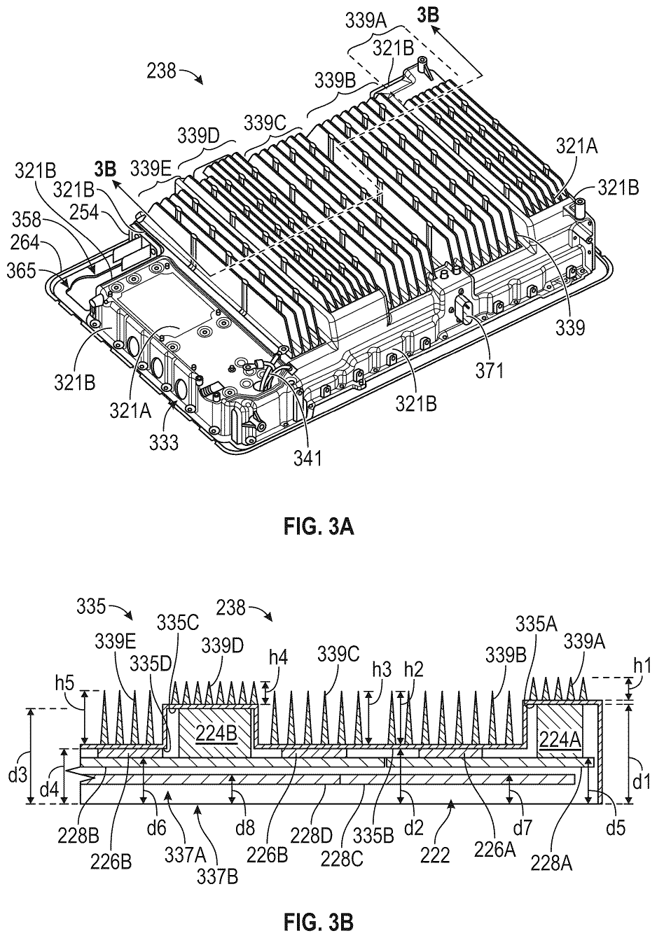

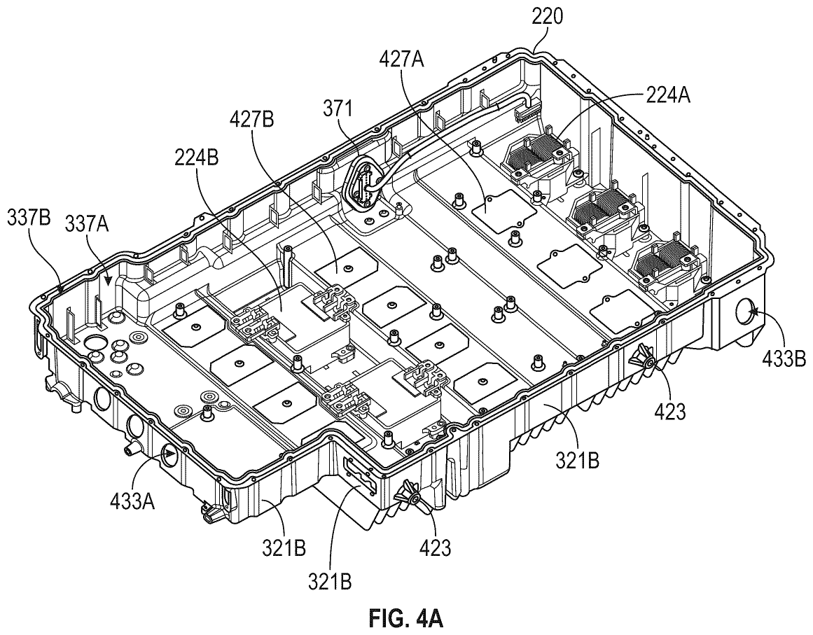

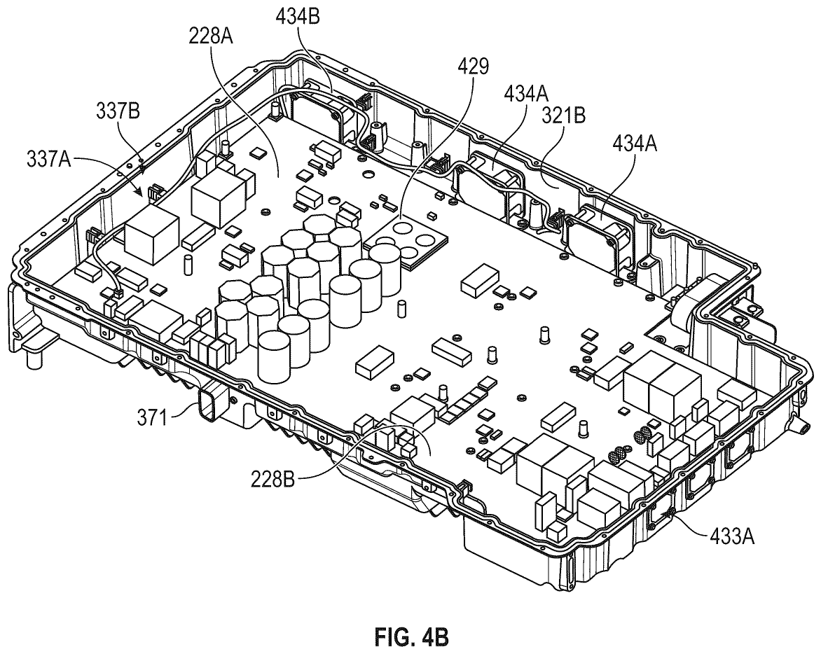

In some embodiments, the electronics housing 220 houses electronic components 222. In some embodiments, the electronic components 222 include any one or combination of a power factor correction (PFC) magnetics component 224A, a direct current (DC) magnetics component 224B, a first transistor 226A, a second transistor 226B, a first main power board (MPB1) 228A, a second main power board (MPB2) 228B, an input filter board (IFB) printed circuit board assembly (PCBA) 228C, a power control center (PCC) PCBA 228D, an insulating pad 230, a weather-resistant cover 232, an airflow generating stir device (e.g., airflow generating stir device 434A in FIG. 4B), or an airflow generating venting device (e.g., airflow generating venting device 434B in FIG. 4B). In some embodiments, an input terminal block 254 is coupled to, and/or at least partially disposed in, an opening of the electronics housing 220. In some embodiments, an input terminal block 254 is partly disposed within a cavity (e.g., cavity 337A in FIGS. 3B-4B) of the electronics enclosure 220 and partly disposed external to the cavity. In some embodiments, the electronic components 222 include the input terminal block 254 or a portion thereof. In some embodiments, the input terminal block 254 provides input power to the electronic components 222. In some embodiments, the input terminal block 254 includes terminals inside and outside of the electronics housing 220. In some implementations, a ferrite core is arranged adjacent to or surrounding the terminals inside the electronics housing 220. The ferrite core may reduce or suppress electromagnetic interference (EMI).

In some embodiments, the PFC magnetics component 224A includes an alternating current (AC) magnetics component. In some embodiments, the PFC magnetics component 224A includes any one or combination of a PFC inductor or PFC choke. In some embodiments, the PFC magnetics component 224A boosts energy from an AC input to a DC bus.

In some embodiments, the DC magnetics component 224B includes a transformer. In some implementations, the DC magnetics component 224B includes a dual active bridge transformer. In some implementations, the DC magnetics component 224B includes an air gap to prevent operation in saturation region. In some embodiments, the DC magnetics component 224B transfers power from DC to DC. In some embodiments, the first transistor 226A includes an insulated-gate bipolar transistor (IGBT). In some embodiments, the second transistor 226B includes a MOSFET.

In some embodiments, any one or combination of the PFC magnetics component 224A, DC magnetics component 224B, first transistor 226A, or second transistor 226B are coupled to the electronics enclosure 220. In some implementations, any one or combination of the PFC magnetics component 224A, DC magnetics component 224B, first transistor 226A, or second transistor 226B are directly coupled to the electronics enclosure 220. In some examples, a thermal interface material (TIM) 236 is disposed between any one or combination of the PFC magnetics component 224A, DC magnetics component 224B, first transistor 226A, or second transistor 226B and the electronics enclosure 220 to promote heat transfer therebetween. In some embodiments, the TIM 236 provides a thermally conductive, electrically insulating layer. In some embodiments, the TIM 236 includes a silicone pad, or any other suitable thermally conductive material.

In some embodiments, the electronics housing 220 includes a contact surface (e.g., contact surfaces 427A, 427B in FIG. 4A). In some implementations, the contact surface is formed in the electronics housing 220, such as by any one or combination of machining, etching, blasting, sanding, or ablating, to name a few examples. The first transistor 226A and/or the second transistor 226B may couple to the electronics housing 220 via the contact surface. The contact surface may reduce or eliminate air gaps in the heat transfer path. In some embodiments, the electronics housing 220 includes heat dissipating sections 238 to remove heat generated by the electronic components 222, such as discussed in relation to FIGS. 3A-4B. In some embodiments, a heat flow path is formed from at least one of the PFC magnetics component 224A, DC magnetics component 224B, first transistor 226A, or second transistor 226B to at least one of the heat dissipating sections 238.

In some embodiments, the PFC magnetics component 224A and/or the first transistor 226A are directly coupled to the MPB1 228A. In one example, the PFC magnetics component 224A is mounted to the MPB1 228A without a wire harness. In some implementations, the TIM 236 is disposed between any of the PFC magnetics component 224A or first transistor 226A and the MPB1 228A. In some embodiments, the PFC magnetics component 224A and/or the first transistor 226A are part of the MPB1 228A. In one example, a replacement MPB1 228A may include the PFC magnetics component 224A and/or the first transistor 226A. In some embodiments, the MPB1 228A includes a current sensor feedback circuit and/or a current sensing circuit. In some embodiments, the MPB1 228A monitors and/or controls the airflow generating stir device. In some embodiments, the MPB1 228A is coupled to the electronics housing 220. In some implementations, standoffs and/or fasteners are used to couple the MPB1 228A to the electronics housing 220.

In some embodiments, the DC magnetics component 224B and/or the second transistor 226B are directly coupled to the MPB2 228B. In some implementations, the TIM 236 is disposed between any of the DC magnetics component 224B or second transistor 226B and the MPB2 228B. In some embodiments, the DC magnetics component 224B and/or the second transistor 226B are part of the MPB2 228B. In some embodiments, the MPB2 228B includes a current sensing circuit to sense transformer saturation. In some embodiments, the MPB2 228B includes heatsinks for power dissipation. In some embodiments, the MPB2 228B includes a relay circuit. In some embodiments, the MPB2 228B is coupled to the electronics housing 220. In some implementations, standoffs and/or fasteners are used to couple the MPB2 228B to the electronics housing 220.

In some embodiments, the insulating pad 230 is arranged between the electronics housing 220 and any one or more of the MPB1 228A or the MPB2 228B. In some embodiments, more than one insulating pad 230 is used. In some implementations, a separate insulating pad 230 is used for each of the MPB1 228A and the MPB2 228B. In some embodiments, the insulating pad 230 is attached to the electronics housing 220. In some implementations, the insulating pad 230 is attached to the electronics housing 220 using any one or combination of glue, adhesive, or sealant. In some embodiments, the insulating pad 230 forms cutouts to allow any one or combination of the PFC magnetics component 224A, DC magnetics component 224B, first transistor 226A, or second transistor 226B to directly couple to the electronics enclosure 220 without the insulating pad 230 therebetween. In some embodiments, the insulating pad 230 blocks or restricts heat transfer to portions of the electronics housing 220 in which is it attached, and promotes or concentrates heat transfer to the remaining portions of the electronics housing 220.

In some embodiments, the weather-resistant cover 232 is coupled to an exterior of the electronics housing 220 to cover an opening (e.g., upper opening 433B in FIG. 4A) in the electronics housing 220. In some implementations, the weather-resistant cover 232 forms a vent for air to move through the opening. In some implementations, the weather-resistant cover 232 prevents any one or combination of rain, moisture, or dust from entering the opening.

In some embodiments, the IFB PCBA 228C is coupled to the input terminal block 254. In some implementations, the IFB PCBA 228C is directly coupled to the input terminal block 254. In some embodiments, the IFB PCBA 228C is coupled to the MPB1 228A through a board-to-board connector. In some embodiments, directly coupling the electronic components 222 to one another and/or to the electronics housing 220 minimizes thermal resistance and eliminates a need for intermediary thermal management components, such as standalone heat sinks or thermal pads.

In some embodiments, the PCC PCBA 228D includes a microcontroller. In some implementations, the PCC PCBA 228D includes an ARM microcontroller. In some embodiments, the PCC PCBA 228D includes interface connectors to couple the PCC PCBA 228D to the MPB1 228A and/or the MPB2 228B. In some implementations, a first one or more harnesses connect to the interface connectors of the PCC PCBA 228D and to the MPB1 228A and/or the MPB2 228B. In some examples, the first one or more harnesses include any one or combination of a controller area network (CAN) harness, 24V harness, or power electronics module (PEM) harness. In some implementations, a second one or more harnesses connect to the interface connectors of the PCC PCBA 228D and to the MPB1 228A.

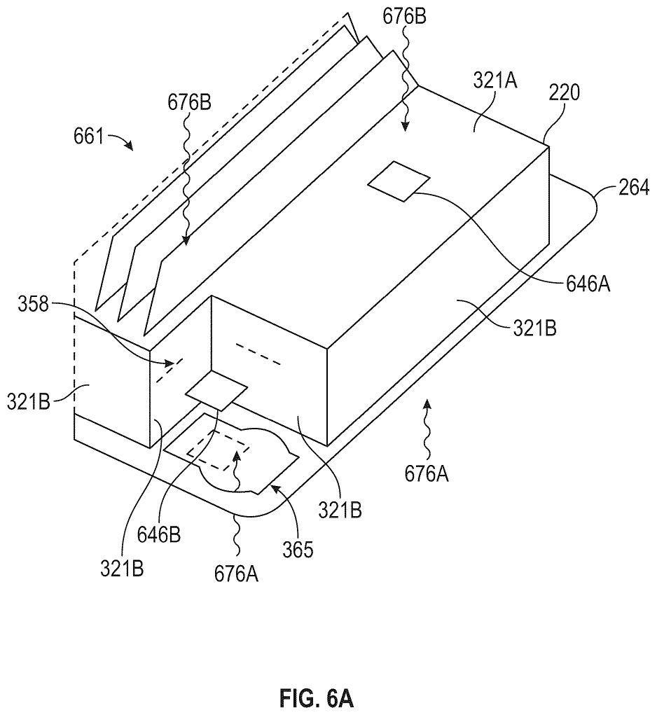

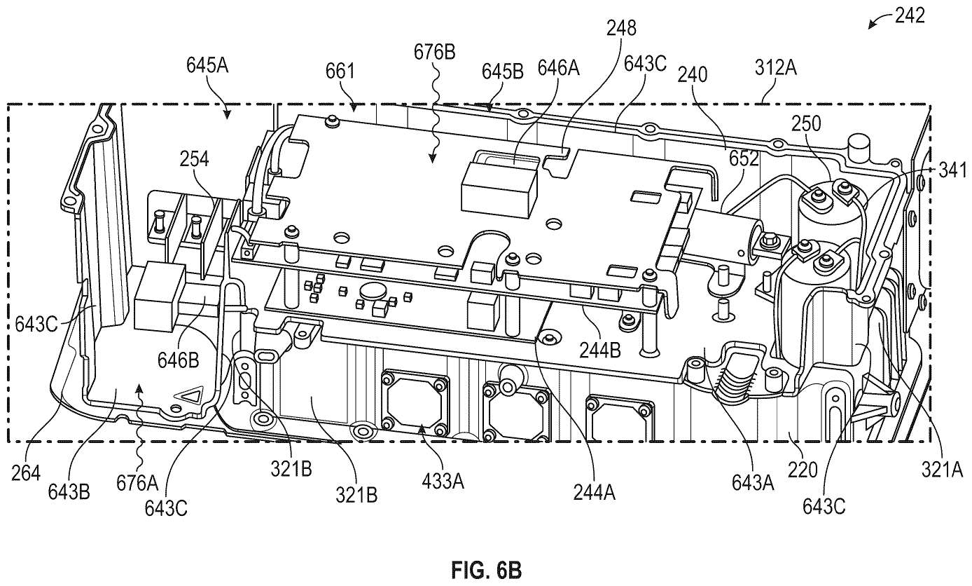

In some embodiments, the service area housing 240 houses field serviceable components 242. In some embodiments, the field serviceable components 242 include any one or combination of an integrated magnetic device (IMD) PCBA 244A, a cluster control unit (CCU) PCBA 244B, a first antenna (e.g., first antenna 646A in FIGS. 6A and 6B), a second antenna (e.g., second antenna 646B in FIGS. 6A and 6B), an antenna cover 248, an electronic switch 250, a fuse (e.g., fuse 652 in FIG. 6B), or the input terminal block 254. In some embodiments, the input terminal block 254 comprises an AC terminal block. In some embodiments, the electronic switch 250 comprises a contactor.

In some embodiments, the IMD PCBA 244A includes an IMD circuit and/or integrated measurement relay (IMR) circuit. In some embodiments, the IMD PCBA 244A places the boost converter on same functional block as IMD circuit. In some embodiments, the BiDi charger 102 is in a black start mode and the IMD PCBA 244A upconverts voltage to start charging. In some implementations, the IMD PCBA 244A upconverts 24 V to 500 V. In some implementations, the IMD PCBA 244A may perform one or more operations, such as perform an isolation test, check impedance of cable to earth to make sure safe to charge, apply large enough voltage, or exceed the expected charge voltage. In some embodiments, the IMD PCBA 244A controls the electronic switch 250. In some embodiments, the IMD PCBA 244A senses temperature. In some embodiments, the IMD PCBA 244A includes an interface connector. In some implementations, the interface connectors enable a wire harness to connect the IMD PCBA 244A to the CCU PCBA 244B.

In some embodiments, the CCU PCBA 244B includes an inter-integrated circuit (I2C) to support a programmable logic controller (PLC) chip for communication with the vehicle. In some embodiments, the CCU PCBA 244B includes an interface connector.

In some embodiments, the field serviceable components 242 are intended to be serviced in the field or at a location of the BiDi charger 102. In some embodiments, the electronic components 222 are not intended to be serviced in the field or at the location of the BiDi charger 102. In some implementations, the electronic components 222 are intended to be serviced at a service or repair center. In some implementations, the electronic components 222 are referred to as non-field serviceable components.

In some embodiments, a service area cover 256 couples to the service area housing 240 to at least partially shield the field serviceable components 242. In some implementations, fasteners couple the service area cover 256 to the service area housing 240. In some examples, the fasteners are removed using standard tooling, such as a Phillips or flat-head screwdriver, hex key, wrench, or socket, to name a few examples, to ensure the field serviceable components 242 can be easily accessed for servicing. Servicing may include any one or combination of, for at least a portion of component, inspecting, removing, replacing, troubleshooting, performing measurements, downloading data from, uploading data to, adjusting, calibrating, adjusting, cleaning, or adding a material to, to name a few examples. In some implementations, a gasket or seal is disposed between the service area cover and the service area housing 240. In some embodiments, the service area cover 256 is referred to as a service housing cover or a housing cover.

In some embodiments, at least one of the MPB1 228A, MPB2 228B, IFB PCBA 228C, PCC PCBA 228D, IMD PCBA 244A, or CCU PCBA 244B includes any one or combination of control circuitry, input/output (I/O) circuitry (e.g., or I/O path), or storage. In some embodiments, the control circuitry may be coupled to any one or combination of sensors, actuators, motors, interfaces, and any other suitable components to control the operations and/or functionality of the BiDi charger 102. In some embodiments, the control circuitry monitors sensor signals, generates control signals, executes computer readable instructions, receives inputs, or a combination thereof. In some embodiments, the control circuitry provides power and/or a data connection to the at least one of the electronic components 222 and/or at least one of the field serviceable components 242.

In some embodiments, at least one of the MPB1 228A, MPB2 228B, IFB PCBA 228C, PCC PCBA 228D, IMD PCBA 244A, or CCU PCBA 244B includes communications circuitry for communicating with other systems. In some implementations, the communications circuitry includes any of an antenna (e.g., the first and/or the second antenna), a transmitter, a receiver, a transceiver, transceiver circuitry or other circuitry, a modulator, a demodulator, or a signal processing unit, or any combination thereof, and may be configured to access the internet, a local area network, wide area network, Bluetooth-enabled device, near field communication (NFC)-enabled device, Wi-Fi enabled device, cellular (e.g., 2G/3G/4G/5G) enabled device, or any other suitable device using any suitable protocol. In some implementations, the communications circuitry is used to communicate (e.g., through the I/O circuitry) with any one or combination of an AGD (e.g., the AGD 104 in FIG. 1), an external device (e.g., the external device 112 in FIG. 1), a vehicle (e.g., the vehicle 110 in FIG. 1), utility equipment (e.g., the utility equipment 106 in FIG. 1), electrical infrastructure (e.g., the electrical infrastructure 108 in FIG. 1), or another system (e.g., another vehicle or a server). In some implementations, the communications circuitry may communicate wirelessly and/or through a wired connection.

In some embodiments, the I/O circuitry receives inputs and/or sends outputs. In some implementations, the I/O circuitry receives inputs from and/or sends outputs to at least one of the vehicle, the AGD, the utility equipment, the electrical infrastructure, the external device, sensors, or the communications circuitry. In some embodiments, the sensors include any one or combination of a temperature sensor, voltage sensor, current transformer, power meter, vibration sensor, or a load sensing device to monitor power or a temperature of the BiDi charger 102. In some embodiments, the I/O circuitry includes, or replaces, the communications circuitry.

In some embodiments, the BiDi charger 102 includes one or more applications to control operations and/or functionality of the BiDi charger 102. In some embodiments, the control circuitry executes a power control application to control power to or from any one or combination of the electronic components 222, the field serviceable components 242, the vehicle, or the AGD. In some embodiments, the control circuitry executes a temperature control application to regulate a temperature of the BiDi charger 102 by controlling power to or from any one or combination of the airflow generating stir device, the airflow generating venting device, or the external airflow generating assembly 270. In some implementations, the temperature control application supports different cooling modes for controlling the fans, such as passive, active, and hybrid, to enable optimal thermal management under varying operating conditions.

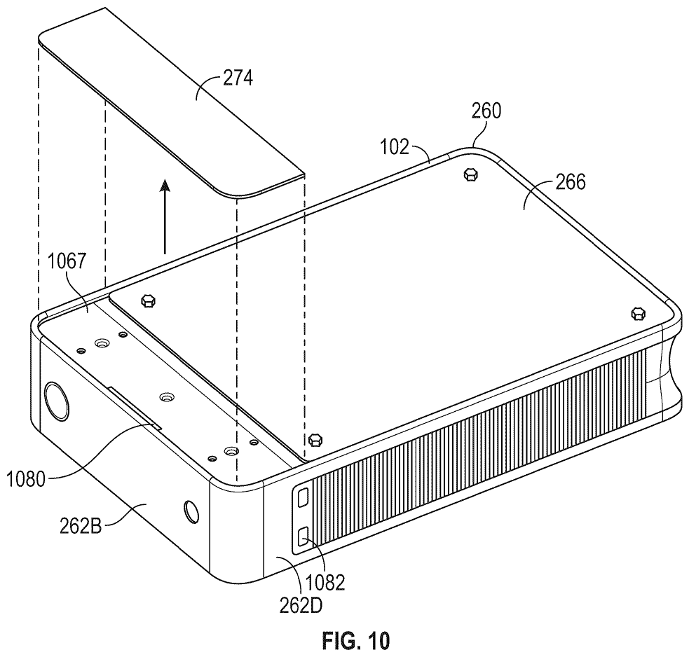

In some embodiments, any one or combination of the control circuitry, I/O circuitry, or communications circuitry executes a communications application to communicate with any one or combination of the vehicle, the AGD, the utility, the electrical infrastructure, or the external device. In some embodiments, the control circuitry executes an input interface application to send or receive an input or output from a user interface. In some implementations, the user interface includes any one or combination of a status indicator light (e.g., light bar assembly 1080 in FIG. 10), a button (e.g., user interface element 1082 in FIG. 10), or the external device. In some embodiments, any of the applications, or a corresponding application, runs on the external device to communicate with the BiDi charger 102. In some embodiments, the application communicates with the external device through a server. In some embodiments, the external device includes a screen, and the user interface includes a graphical user interface (GUI) of the application on the external device.

In some embodiments, the system includes storage. In some embodiments, the storage is an electronic storage device provided that is part of the control circuitry. As referred to herein, the phrase “electronic storage device” or “storage device” should be understood to mean any device for storing electronic data, computer software, or firmware, such as random-access memory, read-only memory, hard drives, optical drives, digital video disc (DVD) recorders, compact disc (CD) recorders, BLU-RAY disc (BD) recorders, BLU-RAY 3D disc recorders, digital video recorders (DVR, sometimes called a personal video recorder, or PVR), solid state devices, quantum storage devices, gaming consoles, gaming media, or any other suitable fixed or removable storage devices, and/or any combination of the same. The storage may be used to store various types of applications as well as data from sensors. In some implementations, nonvolatile memory is also used (e.g., to launch a boot-up routine and other instructions). In some implementations, cloud-based storage or server-based storage is used to supplement storage or instead of the storage.

In some implementations, the storage includes non-transitory memory with non-transitory instructions, that when executed, cause the execution of applications to control aspects of the accessories and/or performance characteristics of the vehicle. In one example, the control circuitry and I/O circuitry are part of the computer having the non-transitory memory. In some embodiments, the instructions are provided by the control circuitry through the I/O circuitry and/or communications circuitry.

In some embodiments, any one of combination of the MPB1 228A, MPB2 228B, IFB PCBA 228C, or PCC PCBA 228D is referred to as a board, circuit board, printed circuit board, or PCBA, to name a few examples. In some embodiments, any one of combination of the MPB1 228A, MPB2 228B, IFB PCBA 228C, or PCC PCBA 228D may provide functionality that is different than previously discussed. In some embodiments, any one of combination of the PFC magnetics component 224A, DC magnetics component 224B, first transistor 226A, or second transistor 226B may be referred to as a component, an electronic component, or an electrical component, to name a few examples. In some embodiments, any one of combination of the PFC magnetics component 224A, DC magnetics component 224B, first transistor 226A, or second transistor 226B may provide functionality that is different than previously discussed.

In some embodiments, the enclosure 260 includes a top ribbon 262A, bottom ribbon 262B, left-side ribbon 262C, right-side ribbon 262D, electronics housing cover 264, and a removable front cover 266. The enclosure forms an internal space (e.g., internal space 968 in FIG. 9). In some embodiments, any one or combination of the electronics housing 220, the service area housing 240, or the external airflow generating assembly 270 are arranged within the internal space.

In some embodiments, the ribbons 262A-262D are coupled to one another. In some implementations, the ribbons 262A-262D are coupled together using any one or combination of glue, adhesive, sealant, or fasteners. In some embodiments, the ribbons 262A-262D are not intended to be decoupled. In some implementations, the ribbons 262A-262D are integrally formed. For example, two or more of the ribbons 262A-262D may be machined out of a single billet of material, molded or printed as a single piece, welded or bonded together, or otherwise joined to together to function as a single article. In some embodiments, at least one of the ribbons 262A-262D is removably coupled to the other ribbons 262A-262D.

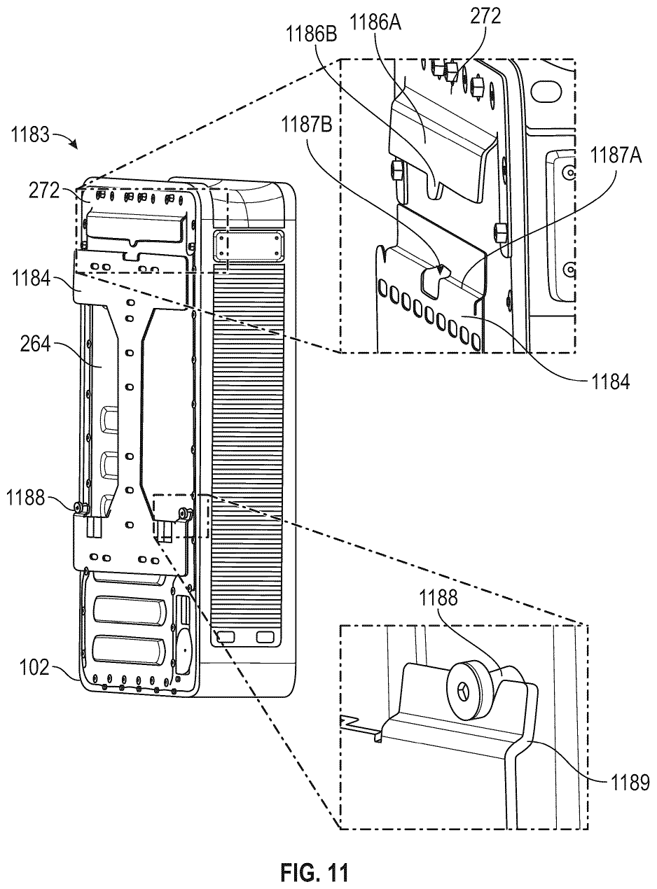

In some embodiments, the ribbons 262A-262D are coupled to the electronics housing cover 264 and the front cover 266. In some implementations, the ribbons 262A-262D are coupled to the electronics housing cover 264 using any one or combination of glue, adhesive, sealant, or fasteners. In some embodiments, the electronics housing cover 264 couples to the electronics housing 220 to ensure the electronic components 222 cannot be easily accessed. In some embodiments, the electronics housing 220 is referred to as a body and the electronics housing cover 264 is referred to as a body cover. In some embodiments, the electronics housing 220 is referred to as a housing and the electronics housing cover 264 is referred to as a housing cover. In some implementations, the ribbons 262A-262D are removably coupled to the electronics housing cover 264 to enable the electronics housing 220 to be removed for servicing. In some embodiments, the electronics housing cover 264 includes a mounting cleat 272 to couple the BiDi charger 102 to a surface, such as a wall, as discussed in relation to FIG. 11.

In some embodiments, the front cover 266 is removably coupled to one or more of the ribbons 262A-262D using any one or combination of glue, adhesive, sealant, or fasteners. In some implementations, at least one retention feature removably couples the front cover 266 to one or more of the ribbons 262A-262D. For example, the retention features may include any one or combination of hooks, loops, magnetic features, slots, pins, buttons, snaps, or other fasteners. In some embodiments, a noise absorber material, such as a foam, fiberglass, wool, wood fiber, cotton, or polyester, is coupled to a surface of the front cover 266 that faces the electronics housing 220. In some embodiments, a removable accent panel 274 is removably coupled to the front cover 266. In some implementations, at least one retention feature removably couples the accent panel 274 to the front cover 266. In some examples, a magnetic feature of the accent panel 274 engages a magnetic feature of the front cover 266 to hold the second removable panel to the frame. In some embodiments, the magnetic feature is any one of a magnet, magnetic material, or ferromagnetic material. In some implementations, the magnetic feature of the accent panel 274 is one of a magnet or ferromagnetic material and the magnetic material is the front cover 266 is one of the magnet or ferromagnetic material.

In some embodiments, the external airflow generating assembly 270 generates air movement to move air over an exterior surface of the electronics housing to remove heat. In some implementations, the external airflow generating assembly 270 moves air over the heat dissipating sections 238. In some implementations, the external airflow generating assembly 270 pulls in air through venting features in the left-side ribbon 262C and moves the air over the electronics enclosure 220 and out of venting features in the right-side ribbon 262D. In some implementations, the venting features include any one or combination of openings, a mesh, a screen, slots, or louvers. In some implementations the airflow direction is reversed, and air is pulled through the right-side ribbon 262D and moves the air out of the left-side ribbon 262C. In some embodiments, the external airflow generating assembly 270 is electrically coupled to the field serviceable components 242 and/or the electronic components 222. In some embodiments, the external airflow generating assembly 270 is field serviceable. In some implementations, the external airflow generating assembly 270 may be removed from the enclosure 260 to be serviced or replaced, such as discussed in relation to FIG. 9.

In some embodiments, the BiDi charger 102 includes a cooling system to dissipate heat generated by the electronic components 222 and/or the field serviceable components 242. In some implementations, the electronics enclosure 220 includes the cooling system or a portion of the cooling system. In some examples, the airflow generating venting device and/or the airflow generating stir device promotes dissipation and removal of heat from inside the cavity of the electronics enclosure 220 to an exterior or surroundings of the electronics enclosure 220. The heat dissipating sections 238 and the external airflow generating assembly 270 dissipate heat from the exterior of the electronics enclosure 220. A thermal architecture and cooling system of the electronics housing 220 is discussed in relation to FIGS. 3A-5.

FIG. 3A is a schematic illustration of the electronics housing 220, in accordance with embodiments of the disclosure. FIG. 3B is a schematic offset section cutaway illustration of the electronics housing 220 in FIG. 3A, in accordance with embodiments of the disclosure. FIGS. 3A and 3B are herein described together for brevity.

In some embodiments, the electronics housing 220 has a bottom 321A (oriented upwards in the views of FIGS. 3A and 3B) and a plurality of sides 321B (FIG. 3A) or sidewalls that form a cavity 337A having an opening 337B (FIG. 3B). Each of the plurality of sides has a first end coupled to the bottom 321A and a second end forming the opening 337B. In the embodiment depicted in FIGS. 3A and 3B, the bottom 321A has a non-planar, multi-leveled exterior surface and corresponding interior surface 335 (e.g., interior surfaces 335A-335D) to accommodate a service area housing (e.g., the service area housing 240 in FIGS. 2, 6B, 7B, and 9), the electronic components 222 (FIG. 3B), and the heat dissipating sections 238. In some embodiments, there is a constant thickness between the exterior and the interior surfaces of the bottom 321A. In some embodiments, there is a variable thickness between the exterior and the interior surfaces of the bottom 321A.

In the embodiment depicted in FIG. 3A, the electronics housing 220 has six sides 321B and an external antenna recess 358. The antenna recess 358 is external to the electronics housing 220 and forms a through-hole in, or recessed portion of, the electronics housing 220. In an exemplary concept of a recessed portion, the recessed portion may be a concave indentation in an otherwise straight or convex profile. As shown, the antenna recess 358 is formed by two of the six sides 321B that travel inward at a corner of the electronics housing 220. In some embodiments, the sides 321B may be referred to as sidewalls and the two sides 321B that form the antenna recess 358 referred to as recess sidewalls. In some embodiments, the sides 321B form an exterior profile of the electronics housing 220 and the electronics housing 220 forms the antenna recess 358 at least partially inward of the exterior profile. For example, the exterior profile may have a rectangular shape and the antenna recess 358 may be a portion of the rectangular shape that is removed. The portion may be partially inward of the exterior profile entirely within the exterior profile.

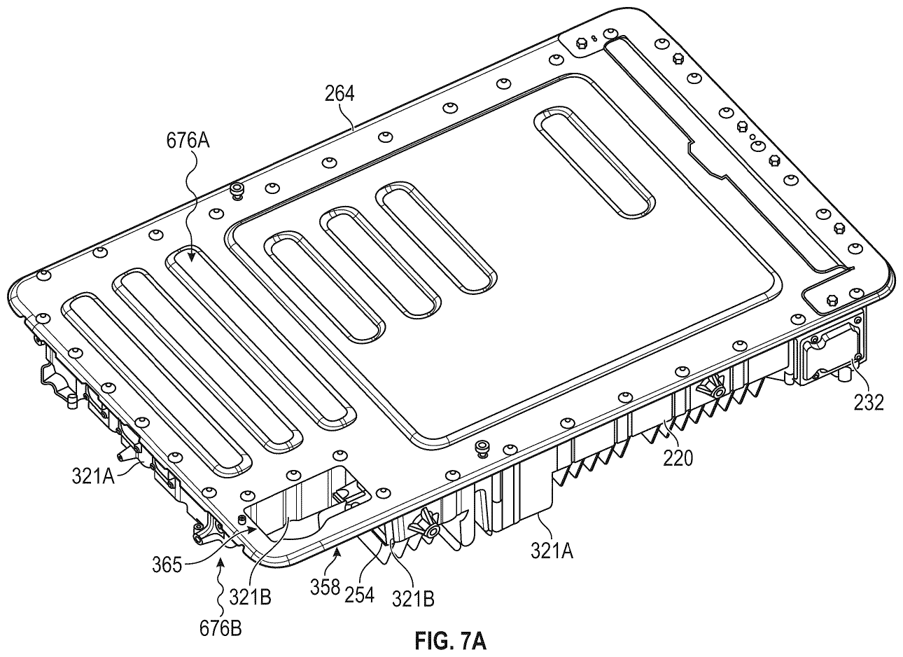

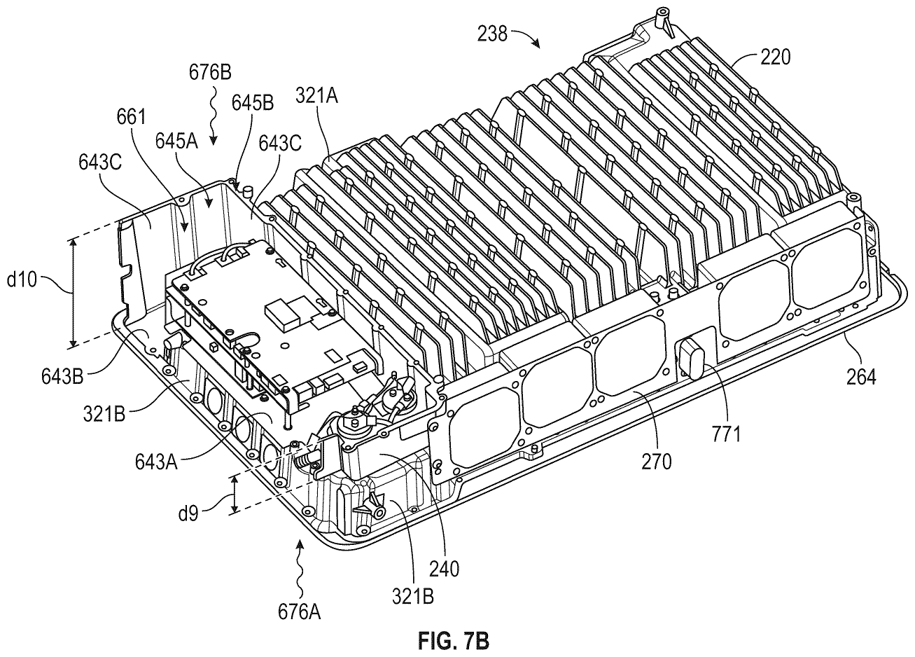

In some embodiments, the input terminal block 254 is arranged in the antenna recess 358. The second ends of the six sides 321B are level with one another such that they form a plane. In some embodiments, the two sides 321B are referred to as recess sidewalls. The electronics housing cover 264 couples to the electronics housing 220 (e.g., to the sides 321B). In some embodiments, the electronics housing cover 264 couples to the second ends of the plurality of sides 321B. The electronics housing cover 264 at least partially covers the opening 337B and extends beyond the sides 321B to form a lip. A portion of the electronics housing cover 264 extends beyond the recess sidewalls and the portion forms a cutout 365. In some embodiments, the cutout 365 is used to allow a signal to pass through the electronics housing cover 264, such as discussed in relation to FIGS. 6A-7.

Referring to FIG. 3B, in some embodiments, the heat dissipating sections 238 include heat dissipating structures 339 (e.g., heat dissipating structures 339A-339E in FIG. 3B) that increase an area of the heat dissipating sections 238 available for heat transfer. The heat dissipating structures 339 may be coupled to or integrally formed with the exterior surface of the bottom 321A. In the embodiment depicted in FIGS. 3A and 3B, the heat dissipating structures 339 are cooling fins that are integrally formed with the electronics housing 220. For example, the electronics housing 220 and the heat dissipating structures 339 may be machined out of a single billet of material, molded or printed as a single piece, welded or bonded together, or otherwise joined to together to function as a single article. In some implementations, the electronics housing 220 is casted as one piece, which may allow space flexibility for the electronic components. In some implementations, each of the cooling fins extends in the same direction. In some implementations, cooling fins corresponding to one of the heat dissipating structures 339 extend in a different direction than cooling fins corresponding to at least one other heat dissipating structure 339. The electronics housing 220 may have a dual purpose, such as a housing and a heat sink.

In the embodiment depicted in FIG. 3B, the heat dissipating structures 339 include a first heat dissipating structure 339A, a second heat dissipating structure 339B, a third heat dissipating structure 339C, a fourth heat dissipating structure 339D, and a fifth heat dissipating structure 339E. In some embodiments, the shape of at least a portion of the heat dissipating structures 339 may differ. For example, the shape may be any one or combination of triangular, rectangular, scalloped, or trapezoidal, to name a few examples. In some implementations, heat dissipating structures 339 include any one or combination of pin fins, louvered fins, corrugated fins, flat fins, inverted trapezoidal fins, ribs, a heat spreader, or a heat sink, to name a few examples. In some implementations, the heat dissipating structures 339 may have a fin surface of any one or combination of plain rectangular, plain triangular, wavy, offset strip, perforated, or louvered.

Referring again to FIG. 3B, in some embodiments, the first heat dissipating structure 339A has a first height (h1). The second heat dissipating structure 339B has a second height (h2). The third heat dissipating structure 339C has a third height (h3). The fourth heat dissipating structure 339D has a fourth height (h4). The fifth heat dissipating structure 339E has a fifth height (h5). In some embodiments, the first and fourth height are a same or substantially similar height, such as within 0.2 in of one another, within 0.15 in, within 0.1 in, within 0.05 in, or within 0.01 in. In some embodiments, the first and fourth height are a different height. In some embodiments, the second, the third, and the fifth height are a same or substantially similar height. In some embodiments, any of the second, the third, or the fifth height are a different height from another. In some embodiments, any one or combination of the second, the third, or the fifth height is a higher height than any one or combination of the first or fourth height.

Referring again to FIG. 3B in some embodiments, the interior surfaces 335 of the bottom 321A include a first interior surface 335A corresponding to the first heat dissipating structure 339A and respective heat dissipating section 238, a second interior surface 335B corresponding to the second and the third heat dissipating structure 339B, 339C and respective heat dissipating sections 238, a third interior surface 335C corresponding to the fourth heat dissipating structure 339D and respective heat dissipating section 238, and a fourth interior surface 335D corresponding to the fifth heat dissipating structure 339E and respective heat dissipating section 238.

In some embodiments, any one or combination of PFC magnetics component 224A, DC magnetics component 224B, first transistor 226A, second transistor 226B, MPB1 228A, MPB2 228B, IFB PCBA 228C, PCC PCBA 228D is arranged in the cavity 337A at different depths from the opening 337B, such as at different depths from the second ends of the sides 321B.

In the embodiment depicted in FIG. 3B, there are at least two of the second transistors 226B. The PFC magnetics component 224A is coupled to the first interior surface 335A at a first depth (d1). Each of the first transistor 226A and a first of the two second transistors 226B are coupled to the second interior surface 335B at a second depth (d2). The DC magnetics component 224B is coupled to the third interior surface 335C at a third depth (d3). A second of the two second transistors 226B is coupled to the fourth interior surface 335D at a fourth depth (d4).

The MPB1 228A is coupled to the PFC magnetics component 224A and the first transistor 226A at a fifth depth (d5). The MPB2 228B is coupled to each of the two second transistors 226B and the DC magnetics component 224B at a sixth depth (d6). The IFB PCBA 228C is arranged in the cavity 337A such that a bottom surface of IFB PCBA 228C that faces the second interior surface 335B is arranged at a seventh depth (d7). In some embodiments, the IFB PCBA 228C is coupled to the MPB1 228A and/or the MPB2 228B at the seventh depth. The PCC PCBA 228D is arranged in the cavity 337A such that a bottom surface of PCC PCBA 228D that faces the second interior surface 335B and/or the fourth interior surface 335D is arranged at an eighth depth (d8). In some embodiments, the PCC PCBA 228D is coupled to the MPB1 228A and/or the MPB2 228B at the eighth depth.

In some embodiments, the first and the third depth are a same or substantially similar depth, such as within 0.2 in of one another, within 0.15 in, within 0.1 in, within 0.05 in, or within 0.01 in. In some embodiments, the first and fourth height are a different depth. In some embodiments, the second and the fourth depth are a same or substantially similar depth. In some embodiments, the second and the fourth depth are a different depth. In some embodiments, the fifth and the sixth depth are a same or substantially similar depth. In some embodiments, the fifth and the sixth depth are a different depth. In some embodiments, the seventh and the eighth depth are a same or substantially similar depth. In some embodiments, the seventh and the eighth depth are a different depth.

In some embodiments, any one or combination of the first or the third depth is a deeper depth than any one or combination of the second, the fourth, the fifth, the sixth, the seventh, or the eighth depth. In some embodiments, any one or combination of the second or the fourth depth is a deeper depth than any one or combination of the fifth, the sixth, the seventh, or the eighth depth. In some embodiments, any one or combination of the fifth or the sixth depth is a deeper depth than any one or combination of the seventh or the eighth depth.

In some embodiments, the heights and depths are based on any one or combination of a stackup of the electronic components 222, an amount of heat generated by the electronic components 222, a TIM (e.g., the TIM 236 in FIG. 2) used and/or whether a TIM is used, a material of the electronic components 222 and/or the electronics housing 220, a process used to manufacture or treat the electronic components 222 and/or the electronics housing 220, or a heat flux and/or thermal conductivity of the electronic components 222 and/or the electronics housing 220. In some embodiments, a different TIM is used between at least one of the PFC magnetics component 224A, DC magnetics component 224B, first transistor 226A, or second transistor 226B and the electronics enclosure 220. In some implementations, the different TIM has a different heat flux and/or thermal conductivity and is determined based at least in part on corresponding heat generated by the PFC magnetics component 224A, DC magnetics component 224B, first transistor 226A, or second transistor 226B.

In some embodiments, the electronics housing 220 and the heat dissipating structures 339 are configured based on the electronic components 222. In the embodiment depicted in FIG. 3B, the first transistor 226A and the second transistor 226B components generate more heat than the PFC magnetics component 224A and the DC magnetics component 224B. The second, the third, and the fifth heat dissipating structures 339B, 339C, 339E, which form part of a heat flow path for, and dissipate heat generated by, the first transistor 226A and the second transistor 226B, have a higher height than the first and the fourth dissipating structures 339A, 339D, which form part of a heat flow path for, and dissipate heat generated by, the PFC magnetics component 224A and the DC magnetics component 224B. The higher height of the second, the third, and the fifth heat dissipating structures 339B, 339C, 339E may increase the surface area and may dissipate heat faster than the first and the fourth dissipating structures 339A, 339D.

In some embodiments, the second interior surface 335B includes two portions, each corresponding to one of the second and the third heat dissipating structure 339B, 339C. In some implementations, the two portions are at different depths. In some examples, one of the two portions is not at the second depth and the other of the two portions is at the second depth. In some embodiments, the first transistor 226A and the first of the two second transistors 226B are coupled to the second interior surface 335B at a different depths, such as when the two portions are at different depths.

Referring to FIG. 3A, in some embodiments, the electronics housing 220 includes a fan harness 271 on an exterior that is electrically coupled to the electronic components 222. In some implementations, a harness or connector of an external airflow generating assembly (e.g., external airflow generating assembly 270 in FIGS. 2, 7B, and 9) is coupled to a fan harness 371. In some embodiments, a transition harness 341 travels through a transition opening in the bottom 321A of the electronics housing 220. In some implementations, the transition opening is in a lower portion of the bottom that is outside of the heat dissipating sections 238. The lower portion may couple to a service area housing (e.g., the service area housing 240 in FIGS. 2, 6B, 7B, and 9). In some implementations, the transition harness 341 comprises a high voltage harness. In some implementations, the transition harness 341 connects to the MPB2 228B (FIG. 3B) at one end and to an electronic switch (e.g., the electronic switch 250 in FIGS. 2 and 6) at the other end. In some embodiments, the electronics housing 220 forms a lower opening 333 in the lower portion to allow airflow into the cavity 337A.

In the embodiment depicted in FIG. 3A, there are three lower openings 333. In some embodiments, more or less may be used.

FIGS. 4A and 4B are schematic illustrations of the electronics housing 220, in accordance with embodiments of the disclosure.

FIG. 4A shows the cavity 337A prior to installation of an insulating pad (e.g., the insulating pad 230 in FIG. 2), a MPB1 (e.g., the MPB1 228A in FIGS. 2, 3B, and 4B), and an MPB2 (e.g., the MPB2 228B in FIGS. 2, 3B, and 4B). The electronics housing 220 includes a first transistor contact surface 427A for a first transistor (e.g., the first transistor 226A in FIGS. 2 and 3B) and a second transistor contact surface 427B for a second transistor (e.g., the second transistor 226B in FIGS. 2 and 3B). In some embodiments, a TIM (e.g., the TIM 236 in FIG. 2) is coupled to or contacts at least one of the contact surfaces 427A, 427B. In some implementations, the contact surfaces 427A, 427B are referred to as TIM regions. In some embodiments, at least one of the contact surfaces 427A, 427B is created by removing material from the electronics housing 220. In some implementations, the electronics housing 220 is machined, etched, blasted, ablated, or otherwise modified to create the contact surfaces 427A, 427B. In some embodiments, at least one of the contact surfaces 427A, 427B is created by adding material to the electronics housing 220. In some implementations, the material is added to the electronics housing 220 by a deposition process such as plating, thermal spray, cold spray, printing, or vapor deposition, to name a few examples. In some implementations, the material may be fastened, glued, adhered, or otherwise attached to the electronics housing 220. The added material may be similar to the material of the electronics housing 220, have similar or different properties (e.g., thermal conductivity or resistivity).

The electronics housing 220 forms a lower opening 433A (or, e.g., lower opening 333 in FIG. 3A) and an upper opening 433B. In some embodiments, a weather-resistant cover (e.g., the weather-resistant cover 232 in FIGS. 2 and 7A) is coupled to an exterior of the electronics housing 220 at the upper opening 433B. In some implementations, the weather-resistant cover forms a vent for air to exit the cavity 337A through the upper opening 433B and the vent. In some implementations, the weather-resistant cover prevents external environmental elements, such as rain, moisture, or dust, to name a few examples, from entering the cavity 337A through the upper opening 433B. In some implementations, the weather-resistant cover includes any one or combination of a passageway for air to move through, a mesh, screen, or filter to prevent dust and/or debris intrusion, a water repellent seal or port to prevent water intrusion, or a one-way valve to prevent air from outside the cavity 337A from moving through the passageway. In some embodiments, the lower opening 433A is used to move air into the cavity 337A. In the embodiment depicted in FIG. 4A, the lower opening 433A includes a feature to prevent external environmental elements from entering the cavity 337A through the lower opening 433A. In some examples, the feature includes at least one of the features of the weather-resistant cover. In one example, the weather resistant cover is coupled to the exterior of the electronics housing 220 at the lower opening 433A.

In some embodiments, an airflow generating venting device (e.g., airflow generating venting device 434B in FIG. 4B) is coupled to the electronics housing 220 at the upper opening 433B. In some implementations, the airflow generating venting device is attached to an interior surface (e.g., the interior surface 335 in FIG. 3B) of the electronics housing 220. In some examples, the airflow generating venting device is attached to the interior surface of a side (e.g., the side 321B in FIGS. 3A, 4A, 4B, and 6-7B) of the electronics housing 220. In some implementations, the airflow generating venting device is attached to an exterior surface of the electronics housing 220. The airflow generating venting device moves air out of the cavity 337A through the upper opening 433B. In some implementations, the air is heated air that is heated by the electronic components 222. In some implementations, the airflow generating venting device pulls air into the cavity 337A through the lower opening 433A.

In some embodiments, the electronics housing 220 includes attach points 423. In some implementations, the attach points 423 are on a side 321B of the electronics housing 220 that is adjacent to a left-side ribbon (e.g., the left-side ribbon 262C in FIGS. 2 and 9) of an enclosure (e.g., the enclosure 260 in FIGS. 2, 9, and 10). In some embodiments, transport hardware couples to the attach point 423. In some implementations, the transport hardware includes a handle or a knob for moving or carrying a BiDi charger (e.g., the BiDi charger 102 in FIGS. 1, 2, and 9-11). The transport hardware may be installed when the left-side ribbon is not coupled to the enclosure.

In the embodiment depicted in FIG. 4A, there are three PFC magnetics components 224A, two DC magnetics components 224B, three first transistor contact surfaces 427A (corresponding to three first transistors), and eight second transistor contact surfaces 427B (corresponding to eight second transistors). In some embodiments, more or less may be used.

FIG. 4B shows the embodiment of FIG. 4A after installation of the MPB1 228A, the MPB2 228B, an airflow generating stir device 434A, and the airflow generating venting device 434B, amongst other components. FIG. 4B also shows the cavity 337A prior to installation of a IFB PCBA (e.g., the IFB PCBA 228C in FIGS. 2 and 3B) and a PCC PCBA (e.g., the PCC PCBA 228D in FIGS. 2 and 3B). In some embodiments, a busbar 429 couples and/or electrically couples the MPB1 228A to the MPB2 228B.

In some embodiments, any one or combination of the airflow generating stir device 434A or airflow generating venting device 434B are coupled to the electronics housing 220. In some implementations, the airflow generating stir device 434A and/or the airflow generating venting device 434B are coupled to an interior of the electronics housing 220. In some implementations, the airflow generating stir device 434A and/or the airflow generating venting device 434B are coupled to a side 321B of the electronics housing 220. In some examples, the side 321B is adjacent to a left-side ribbon (the left-side ribbon 262C in FIGS. 2 and 9) of an enclosure (e.g., the enclosure 260 in FIGS. 2, 9, and 10).

In some embodiments, the airflow generating stir device 434A generates air movement to circulate and/or stir air around a space. In some implementations, the airflow generating stir device 434A stirs air inside the cavity 337A. In the embodiment depicted in FIG. 4B, the airflow generating stir device 434A includes a stir fan to move air around the cavity 337A. In some embodiments, the airflow generating venting device 434B generates air movement to move air into the cavity 337A from outside of the cavity 337A (e.g., through the lower opening 433A) and/or to move air from inside the cavity 337A to outside the cavity 337A (e.g., through the upper opening 433B). In some implementations, the airflow generating venting device 434B moves heated air from inside the cavity 337A, such as air that is heated by electronic components (e.g., the electronic components 222 in FIGS. 2 and 3B), to outside the cavity 337A and external to the electronics housing 220. In some implementations, the airflow generating venting device 434B moves air into, through, and out of the cavity 337A to bring in air and remove heated air. In some embodiments, an airflow generating device or assembly (e.g., airflow generating stir device 434A, airflow generating venting device 434B, or external airflow generating assembly 270) comprises any one or combination of a fan, blower, ventilator, propellor, or any device that may generate airflow, to name a few examples. In some embodiments, the use or inclusion of the airflow generating stir device 434A and/or the airflow generating venting device 434B is optional. For example, a layout or arrangement of the electronic components 222, the TIM, and the heat dissipating sections 238 may create heat flow paths that dissipate heat generated from the electronic components 222 without the airflow generating stir device 434A and/or the airflow generating venting device 434B fan, such as through natural convection.

In some embodiments, standoffs are used to provide space or a gap between any one or combination of the MPB1 228A, the MPB2 228B, the IFB PCBA, or the PCC PCBA. The space or gap may promote air circulation within the cavity 337A and/or air movement through the cavity 337A. The air movement or circulation may improve heat transfer.

In the embodiment depicted in FIG. 4B, there are two airflow generating stir devices 434A and one airflow generating venting device 434B. In some embodiments, more or less may be used.

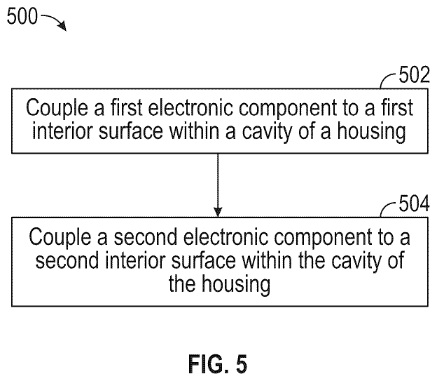

FIG. 5 is a flowchart of an illustrative process 500 for installing electronic components (e.g., the electronic components 222 in FIGS. 2 and 3B) in an electronics housing (e.g., the electronics housing 220 in FIGS. 2, 4A, 6-7B, and 9), in accordance with embodiments of the disclosure.

The process 500 begins at operation 502 with coupling a first electronic component (e.g., one of PFC magnetics component 224A, DC magnetics component 224B, first transistor 226A, or second transistor 226B in FIGS. 2, 3B, and 4A) to a first interior surface (e.g., one of the interior surfaces 335A-335D in FIG. 3B) within a cavity (e.g., the cavity 337A in FIGS. 3B-4B) of a housing (e.g., the electronics housing 220 in FIGS. 2, 4A, 6-7B, and 9), such as described above with respect to FIGS. 2, 3B, and 4A. In some embodiments, the housing includes a first heat dissipating structure (e.g., one of the heat dissipating structures 339A-339E in FIGS. 3A and 3B) coupled to a first exterior surface of the housing. The first heat dissipating structure removes a first amount of heat. The housing further includes a second heat dissipating structure (e.g., a different one of the heat dissipating structures 339A-339E in FIGS. 3A and 3B) coupled to a second exterior surface of the housing. The second heat dissipating structure removes a second amount of heat. The first interior surface is opposite the first exterior surface of the housing.

The process 500 continues to operation 504 with coupling a second electronic component (e.g., a different one of PFC magnetics component 224A, DC magnetics component 224B, first transistor 226A, or second transistor 226B in FIGS. 2, 3B, and 4A) to a second interior surface (e.g., a different one of the interior surfaces 335A-335D in FIG. 3B) within the cavity of the housing, such as described above with respect to FIGS. 2, 3B, and 4A. In some embodiments, the second interior surface is opposite the second exterior surface of the housing.

FIG. 5 is an illustrative example of a method, and other methods including fewer, additional, or alternative steps are possible consistent with this disclosure. Various modifications can be made to the process 500 in accordance with various embodiments disclosed herein. In some embodiments, process 500 is a manual process and at least one of its operations is performed by a user or operator. In some embodiments, process 500 is an automated process and at least one of its operations is performed using control circuitry.

In some embodiments, the BiDi charger 102 includes an antenna system (e.g., antenna system 661 in FIGS. 6A, 6B, and 7B) to enable communication (e.g., BiDi communication) with the BiDi charger 102. For example, the antenna system may communicate with an external device (e.g., the external device 112 in FIG. 1) or system. In some implementations, the antenna system comprises a dual antenna system (e.g., first antenna 646A and second antenna 646B in FIGS. 6A and 6B). In some implementations, the antenna system enables compact packing of components (e.g., the electronic components 222 in FIGS. 2 and 3B and/or the field serviceable components 242 in FIGS. 2 and 6) of the BiDi charger. An architecture for a dual antenna system is discussed in relation to FIGS. 6A-8.

FIGS. 6A and 6B are schematic illustrations of an arrangement of components of an antenna system 661 of a bi-directional charger (e.g., the BiDi charger 102 in FIGS. 1, 2, and 9-11), in accordance with embodiments of the disclosure. FIGS. 6A and 6B show different view perspectives to facilitate discussion of the antenna system 661.

FIG. 6A shows a position of a first antenna 646A and a second antenna 646B in relation to the electronics housing 220 and the electronics housing cover 264. In the depicted embodiment, some features, such as an input terminal bock (e.g., the terminal block 254 in FIGS. 2, 3A, 6B, and 7A) and lower openings (e.g., the lower opening 333, 433A in FIGS. 3A, 4A, 4B, and 6B), have been omitted to avoid overcomplicating the drawing.

The electronics housing 220 includes the bottom 321A and the sides 321B. The bottom 321A and the sides 321B form a cavity (e.g., the cavity 337A in FIGS. 3B-4B) of the electronics housing 220 and two of the sides 321B form the antenna recess 358. When the electronics housing cover 264 is coupled to the electronics housing 220, a portion of the electronics housing cover 264 extends beyond the sides 321B of the electronics housing 220. The first antenna 646A is disposed adjacent to the bottom 321A and external to the cavity of the electronics housing 220. The second antenna 646B is disposed adjacent to at least one of the sides 321B (e.g., the two sides 321B) and external to the cavity. In some embodiments, the second antenna 646B is disposed adjacent to the electronics housing cover 264. In some implementations, the second antenna 646B is disposed adjacent to the cutout 365 of the electronics housing cover 264. In the embodiment depicted in FIG. 6A, dashed lines show orthogonal projections of the second antenna 646B on the two sides 321B and a dashed rectangle shows the orthogonal projection of the second antenna 646B in the cutout 365. In some embodiments, the second antenna 646B is positioned such that at least one of the orthogonal projections is at a different location of the side 321B or the electronics housing cover 264.

The positions of the first and the second antenna 646A, 646B may affect communication with the BiDi charger. In the embodiment depicted in FIG. 6A, the first and the second antenna 646A, 646B are arranged such that a first signal 676A passing in a first direction is capable of being received at the second antenna 646B without passing through the electronics housing 220. In some embodiments, the first signal 676A passes through the cutout 365 and the antenna recess 358 and is received at the second antenna 646B. In some embodiments, the first signal 676A is not capable of being received at the first antenna 646A without passing through the electronics housing 220. In some embodiments, the first signal 676A must pass through the electronics housing 220 to be received at the first antenna 646A. In some embodiments, the first signal 676A is at least one of attenuated by the electronics housing 220 as it travels to the first antenna 646A, degraded by the electronics housing 220 as it travels to the first antenna 646A, or blocked by the electronics housing 220 from reaching the first antenna 646A. In some embodiments, the first signal 676A must pass through the electronics housing cover 264 and/or the cavity of the electronics housing 220 to be received at the first antenna 646A. In some embodiments, the first signal 676A is at least one of attenuated, degraded, or blocked by the electronics housing cover 264 and/or at least one electronic component (e.g., of the electronic components 222 in FIGS. 2 and 3B) of the electronics housing 220 as it travels to the first antenna 646A. Thus, if only one of the first or the second antenna 646A, 646B is used, then the BiDi charger may have difficulty communicating with other devices (e.g., the external device 112 in FIG. 1) or systems (e.g., the AGD 104, utility equipment 106, electrical infrastructure 108, or vehicle 110 in FIG. 1).

In the embodiment depicted in FIG. 6A, the first and the second antenna 646A, 646B are arranged such that a second signal 676B passing in a second direction is capable of being received at the first antenna 646A without passing through the electronics housing 220. In some embodiments, the second direction is opposite the first direction. In some embodiments, the second signal 676B is capable of being received at the second antenna 646B. In some implementations, the second signal 676B is capable of being received at the second antenna 646B without passing through the electronics housing 220. In some implementations, the second signal 676B passes through the antenna recess 358 and is received at the second antenna 646B. In some embodiments, the second signal 676B is at least one of attenuated, degraded, or blocked by the electronics housing 220 (e.g., by the bottom 321A and/or one of the sides 321B) as it travels to the second antenna 646B. Thus, if only one of the first or the second antenna 646A, 646B is used, then the BiDi charger may have difficulty communicating with other devices or systems. For example, the BiDi charger may be able to communicate with devices transmitting a signal in the second direction but not with devices transmitting a signal in the first direction.

In some embodiments, the second antenna 646B is positioned closer to the electronics housing cover 264 or the cutout 365 thereof than what is shown in FIG. 6A. In some implementations, positioning the second antenna 646B closer to cutout 365 reduces or eliminates attenuation, degradation, or blocking of the first signal 676A as it travels to the second antenna 646B. In some implementations, positioning the second antenna 646B closer to cutout results in attenuation, degradation, or blocking of the second signal 676B by the electronics housing 220 as it travels to the second antenna 646B.

In some embodiments, any one or combination of the bottom 321A, the side 321B, or the electronics housing cover 264 comprises a material that blocks, attenuates, or deprecates the first and/or the second signal 676A, 676B. In some implementations, any one or combination of the bottom 321A, the side 321B, or the electronics housing cover 264 comprises a metallic material. In some embodiments, at least a portion of the electronics housing cover 264 comprises a material that allows the first signal 676A to be capable of being received at the second antenna 646B without passing through the electronics housing 220. In some implementations, the material is a non-metallic material. In some implementations, the second antenna 646B is disposed adjacent to the portion of the electronics housing cover 264 that comprises the material.

In some embodiments, an orientation of the BiDi charger affects communication with the first and/or the second antenna 646A, 646B. In some implementations, the BiDi charger is mounted to a structure, such as a wall, which attenuates or degrades the first signal 676A as it travels through the structure and towards the first or the second antenna 646A, 646B. In some examples, positioning the second antenna 646B at any one or combination of adjacent to at least one side 321B, external to the cavity, or in-line with the cutout 365 enables adequate communication with the BiDi charger via the second antenna 646B. In some examples, the electronics housing 220 and/or the electronic components in combination with the structure attenuates or degrades the first signal 676A to a signal loss value that is inadequate for communication with the BiDi charger via the first antenna 646A. Thus, if the second antenna 646B is not present and positioned as previously discussed, then communication with the BiDi charger may be impeded.

In some implementations, a wireless signal is attenuated or degraded based on a direction of the wireless signal. In some examples, a wireless signal passing in a third direction that is at an acute angle to the BiDi charger may be at least one of attenuated, degraded, or blocked by components of the BiDi charger as it travels to the first or the second antenna 646A, 646B. The components of the BiDi charger may include any one or combination of the electronics housing 220, the electronics housing cover 264, or an enclosure (e.g., the enclosure 260 in FIGS. 2, 9, and 10), to name a few examples. The acute angle may be measure from a surface of a component of the BiDi charger. In some examples, positioning the first antenna 646A at any one or combination of adjacent to the bottom 321A or external to the cavity and/or positioning the second antenna 646B at any one or combination of adjacent to at least one side 321B, external to the cavity, or in-line with the cutout 365 enables adequate communication with the BiDi charger via the first or the second antenna 646A, 646B. Thus, if the first and the second antenna 646A, 646B are not present and positioned as previously discussed, then communication with the BiDi charger may be impeded.

FIG. 6B shows the antenna system 661 positioned in the service area housing 240 of the BiDi charger. In some embodiments, the antenna system 661 includes the first antenna 646A, the second antenna 646B, and communications circuitry, such as the communications circuitry discussed in relation to FIG. 2. In some embodiments, the CCU PCBA 244B comprises the communications circuitry. In some embodiments, at least one of the first or the second antenna 646A, 646B is electronically coupled to the communications circuitry. In some embodiments, both the first and the second antenna 646A, 646B are used to communicate at a same time or during a same time period. In some embodiments, the first antenna 646A is a primary antenna and/or a CCU antenna. In some embodiments, the second antenna 646B is a secondary antenna. In some embodiments, the first and the second antenna 646A, 646B do not have an inherent priority, order, or rank. In some embodiments, one of the first or the second antenna 646A, 646B may be prioritized based on a request to establish communication with the BiDi charger or ongoing communication with the BiDi charger. In some embodiments, the communications circuitry receives at least one of the first or the second signal 676A, 676B. In some implementations, the communications circuitry controls the electronic switch 250 based at least in part on receiving the first and/or the second signal 676A, 676B. In some embodiments, the communications circuitry is external to the cavity of the electronics housing 220. In some embodiments, the communications circuitry is disposed between the bottom 321A and the first antenna 646A. In some embodiments, the second antenna 646B is disposed between the electronics housing cover 264 and the input terminal block 254.

In some embodiments, the antenna system 661 is at least partially arranged in the service area housing 240. In the embodiment depicted in FIG. 6B, the service area housing 240 includes a first bottom 643A, a second bottom 643B, and a plurality of sides 643C that at least partially form a compartment 645A having an opening 645B. The antenna system 661 is at least partially arranged in the compartment 645A. In some embodiments, at least a portion of the field serviceable components 242 are arranged in the compartment 645A.

Each of the plurality of sides 643C has a first end coupled to at least one of the first or the second bottom 643A, 643B and a second end forming the opening 645B. An interior surface of the first bottom 643A is at a ninth depth (d9) from the opening 645B and an interior surface of the second bottom 643B is at a tenth depth (d10) from the opening 645B. In some embodiments, the ninth and the tenth depths are measured from the second ends of the sides 643C. In some embodiments, the tenth depth is deeper than the ninth depth.

In some embodiments, the first bottom 643A is coupled to the bottom 643A of the electronics housing 220. The second bottom 643B is arranged adjacent to the electronics housing cover 264. In some embodiments, the second bottom 643B is coupled to the electronics housing cover 264. In some embodiments, the second bottom 643B is arranged adjacent to, and/or coupled to, one of the sides 321B of the electronics housing 220. The first antenna 646A is arranged in the compartment 645A and disposed adjacent to the opening 645B. The second antenna 646B is arranged in the compartment 645A and disposed adjacent to the second bottom 643B. The first signal 676A passes (e.g., in the first direction) through the second bottom 643B and is capable of being received at the second antenna 646B. In some embodiments, the second bottom 643B is arranged in an antenna recess (e.g., the antenna recess 358 in FIGS. 3A and 7A) of the electronics housing 220. The second antenna 646B is arranged in the compartment 645A and disposed adjacent to the second bottom 643B. In some embodiments, the second antenna 646B is coupled to the second bottom 643B. In some embodiments, at least a portion of the service area housing 240 (e.g., the second bottom 643B) comprises a non-metallic material. In some embodiments, at least a portion of the service area housing 240 (e.g., the second bottom 643B) does not comprise a metallic material.

In the embodiment depicted in FIG. 6B, a fuse 652 and/or the electronic switch 250 is coupled to the first bottom 643A. The IMD PCBA 244A is coupled to the first bottom 643A. The CCU PCBA 244B is coupled to the first bottom 643A and/or the IMD PCBA 244A. The antenna cover 248 is coupled to the CCU PCBA 244B. In some implementations, standoffs and/or fasteners are used to couple any one or combination of the IMD PCBA 244A, the CCU PCBA 244B, or the antenna cover 248 to one another or to the service area housing 240. In some implementations, the first antenna 646A is coupled to the first antenna 646A.

In some embodiments, the BiDi charger uses the antenna system 661 to enable a portion of communications, or all communications, with external systems and/or devices (e.g., any one or combination of the AGD 104, the utility equipment 106, the electrical infrastructure 108, or the vehicle 110, or the external device 112 in FIG. 1). In some implementations, the communications application and/or the input interface application executes on the control circuitry to provide instructions to the control circuitry to send or receive data or information to the external systems or devices, such as discussed in relation to FIG. 2.

In some embodiments, the antenna system 661 is arranged in an enclosure (e.g., the enclosure 260 in FIGS. 2, 9, and 10).

In some embodiments, the antennas are used to send (or, e.g., transmit) and receive signals. Although the first and the second signal 676A, 676B are shown traveling towards the first and the second antenna 646A, 646B, respectively, at least one of the first or the second signal 676A, 676B may travel away from the first or the second antenna 646A, 646B.

In the embodiment depicted in FIG. 6B, there are two electronic switches 250. In some embodiments, more or less may be used. In the embodiment depicted in FIGS. 6A and 6B, there are two antennas (e.g., the first and the second antenna 646A, 646B). In some embodiments, more antennas may be used.

FIGS. 7A and 7B are schematic illustrations of the antenna system 661 of a BiDi charger (e.g., the BiDi charger 102 in FIGS. 1, 2, and 9-11), in accordance with embodiments of the disclosure. As shown the electronics housing 220 is coupled to the electronics housing cover 264.

FIG. 7A shows the first and the second signals 676A, 676B in relation to a first orientation of the electronics housing 220. A service area housing (e.g., the service area housing 240 in FIGS. 2, 6B, 7B, and 9) is omitted for clarity and ease of discussion. The first orientation is for illustrative purposes and does not necessarily reflect an orientation relating to the BiDi charger. In the first orientation, the electronics housing cover 264 faces upwards on the page. The first and the second signals 676A, 676B are shown in relation to the first orientation. The first signal 676A passes through the cutout 365 of the electronics housing cover 264 and the antenna recess 358 of the electronics housing 220, but does not pass through the electronics housing 220, such as discussed in relation to FIG. 6A. The weather-resistant cover 232 is coupled to an exterior of the electronics housing 220.

FIG. 7B shows the first and the second signals 676A, 676B in relation to a second orientation of the electronics housing 220. The second orientation is for illustrative purposes and does not necessarily reflect an orientation relating to the BiDi charger. In the second orientation, the electronics housing cover 264 faces downwards on the page and the bottom 321A of the electronics housing 220 faces upwards. The first and the second signals 676A, 676B are shown in relation to the second orientation. The first bottom 643A of the service area housing 240 is at the ninth depth and the second bottom 643B is at the tenth depth. The external airflow generating assembly 270 is arranged adjacent to one of the sides 321B of the electronics housing 220 and electrically coupled to the fan harness 371. The external airflow generating assembly 270 moves air across the bottom 321A of the electronics housing 220 to remove heat from the heat dissipating sections 238. In some embodiments, the external airflow generating assembly 270 moves heated air that is evacuated from a cavity (e.g., the cavity 337A in FIGS. 3B-4B) of the electronics housing 220, such as discussed in relation not FIG. 4B, away from the electronics housing 220. In some embodiments, the external airflow generating assembly 270 is coupled to an exterior of the electronics housing 220.

In some embodiments, the external airflow generating assembly 270 includes an external fan assembly to move air over the exterior of the electronics housing 220. In the embodiment depicted in FIG. 7B, the external airflow generating assembly 270 includes five fans. In some embodiments, more or less may be used.

As discussed in relation to FIGS. 6A-7B, the wireless signals (e.g., the first and the second signal 676A, 676B) pass in a direction. In some embodiments, each of the wireless signals may not technically pass in a single direction. The wireless signals may comprise electromagnetic waves that oscillate as they travel through space. For example, a wireless signal may change direction as it propagates according to a wave pattern having a wavelength, frequency, amplitude, and/or speed. However, for illustrative purposes, the direction that each wireless signal passes may be considered the overall direction that it propagates. In some embodiments, communication with the BiDi charger is BiDi. For example, the BiDi charger receives the first signal 676A passing in the first direction. The first signal 676A may be sent from an external device or system. The BiDi charger may send or transmit a signal to the device that passes in a direction opposite of the first direction.

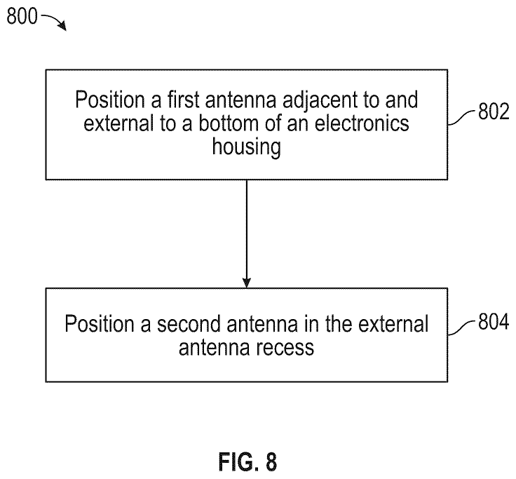

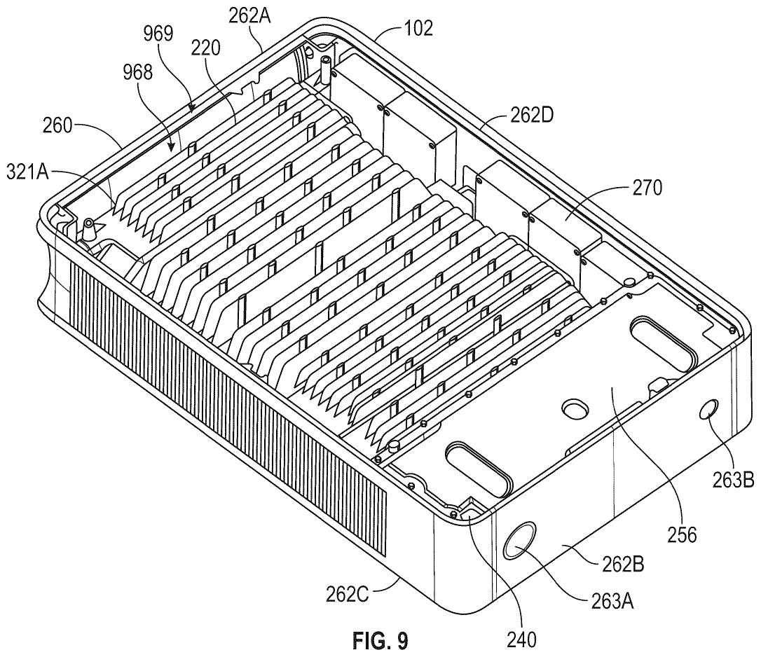

FIG. 8 is a flowchart of an illustrative process 800 for installing an antenna system (e.g., the antenna system 661 in FIGS. 6A, 6B, and 7B) in a BiDi charger (e.g., the BiDi charger 102 in FIGS. 1, 2, and 9-11), in accordance with embodiments of the disclosure.

The process 800 begins at operation 802 with positioning a first antenna (e.g., the first antenna 646A in FIGS. 6A and 6B) adjacent to and external to a bottom (e.g., the bottom 321A in FIGS. 3A, 6-7B, and 9) of an electronics housing (e.g., the electronics housing 220 in FIGS. 2, 4A, 6-7B, and 9), such as described above with respect to FIG. 6A. In some embodiments, the electronics housing comprises the bottom and a plurality of sidewalls (e.g., the sides 321B in FIGS. 3A, 4A, 4B, and 6-7B). The sidewalls form an external antenna recess (e.g., the antenna recess 358 in FIGS. 3A and 7A). An electronics housing cover (e.g., the electronics housing cover 264 in FIGS. 2, 3A, 6-7B, and 11) is coupled to a recessed sidewall (e.g., a side 321B forming an antenna recess 358 in FIGS. 3A and 7A) of the sidewalls. A portion of the electronics housing cover extends over the external antenna recess.

The process 800 continues to operation 804 with positioning a second antenna (e.g., the second antenna 646B in FIGS. 6A and 6B) in the external antenna recess, such as described above with respect to FIGS. 6A, 6B, and 7B. A first signal (e.g., the first signal 676A in FIGS. 6A-7B) passing in a first direction is capable of being received at the second antenna without passing through the electronics housing. The first signal passing in the first direction is not capable of being received at the first antenna without passing through the electronics housing. A second signal (e.g., the second signal 676B in FIGS. 6A-7B) passing in a second direction opposite the first direction is capable of being received at the first antenna without passing through the electronics housing. In some embodiments, positioning the first antenna includes positioning the second antenna between the electronics housing cover and a terminal block.

FIG. 8 is an illustrative example of a method, and other methods including fewer, additional, or alternative steps are possible consistent with this disclosure. Various modifications can be made to the process 800 in accordance with various embodiments disclosed herein. In some embodiments, process 800 is a manual process and at least one of its operations is performed by a user or operator. In some embodiments, process 800 is an automated process and at least one of its operations is performed using control circuitry.

In some embodiments, the BiDi charger 102 includes a particular packing configuration. In some implementations, a design and layout of components for the BiDi charger 102 enables compact packing of BiDi charger 102 components and increases maintainability and serviceability. In some implementations, the design and layout of components increases serviceability and safety of the BiDi charger 102 by allowing easy access to field serviceable components (e.g., the field serviceable components 242 in FIGS. 2 and 6) and restricting access to non-field serviceable components (e.g., the electronic components 222 in FIGS. 2 and 3B). The packing configuration is discussed in relation to FIGS. 9-12.

FIG. 9 is a schematic illustration of components within the enclosure 260 of a BiDi charger (e.g., the BiDi charger 102 in FIGS. 1, 2, and 9-11), in accordance with embodiments of the disclosure.

In some embodiments, the enclosure 260 forms an internal space 968 having an enclosure opening 969. In some implementations, any one or combination of the electronics housing 220, the service area housing 240, or the external airflow generating assembly 270 are arranged within the internal space 968.

In some embodiments, any one of combination of the electronics housing 220 or the service area housing 240 are coupled to the enclosure 260. In some embodiments, a compartment opening (e.g., the opening 645B in FIGS. 6B and 7B) of a compartment (e.g., the compartment 645A in FIGS. 6B and 7B) of the service area housing 240 faces a front cover (e.g., the front cover 266 in FIGS. 2 and 10) of the enclosure 260 (or, e.g., the opening 969). In some examples, field serviceable components (e.g., the field serviceable components 242 in FIGS. 2 and 6) are accessible through the opening of the compartment of the service area housing 240 when the front cover is removed. As shown in FIG. 9, the front cover has been removed and the service area cover 256 would need to be removed (e.g., using standard tools or hardware) to service the field serviceable components.

In some embodiments, a cavity opening (e.g., the opening 337B in FIGS. 3B-4B) of a cavity (e.g., the cavity 337A in FIGS. 3B-4B) of the electronics housing 220 faces away from the front cover of the enclosure 260. In some examples, electronic components (e.g., the electronic components 222 in FIGS. 2 and 3B) are not accessible when the front cover is removed.

As shown in FIG. 9, the electronics housing 220 would need to be removed from the internal space 968 (e.g., by removing the ribbons 262A-262D) and decoupled from an electronics housing cover (e.g., the electronics housing cover 264 in FIGS. 2, 3A, 6-7B, and 11) to access the electronic components. In some embodiments, the electronics housing 220 is coupled to the electronics housing cover such that the cavity opening faces the electronics housing cover. In some embodiments, non-standard or specialty tools or hardware are needed to decouple the electronics housing 220 from the electronics housing cover. In some implementations, any one or combination of a security fastener, tamper-resistant or proof fastener, or lock, to name a few examples, may couple the electronics housing 220 from the electronics housing cover. In some embodiments, the enclosure 260 comprises the electronics housing cover and the ribbons 262A-262D.

In some embodiments, the bottom 321A of the electronics housing 220 faces the front cover of the enclosure 260. The bottom 321A may be referred to as a backside of the electronics housing 220. For example, the backside may be more relevant when an orientation of the electronics housing 220 is such that the bottom 321A does not face down or towards the ground, such as when the electronics housing 220 is arranged in the internal space 968, or when the electronics housing 220 is oriented differently than surrounding components, such as when a bottom (e.g., the first bottom 643A and/or second bottom 643B in FIGS. 6B and 7B) of the service area housing 240 couples to the bottom 321A.

In some embodiments, the external airflow generating assembly 270 is removable from the internal space 968 by removing the right-side ribbon 262D. In some implementations, the front cover is not removed when removing the external airflow generating assembly 270. In some embodiments, the external airflow generating assembly 270 is decoupled from any one or combination of the right-side ribbon 262D, the electronics housing 220, or the service area housing 240 when removed from the internal space 968. In some implementations, the right-side ribbon 262D is not removed when removing the external airflow generating assembly 270.

In some embodiments, the enclosure 260 includes a first enclosure knockout 263A or opening for input power. In some implementations, the first enclosure knockout 263A provides access to an input terminal block (e.g., the input terminal block 254 in FIGS. 2, 3A, 6B, and 7A). In some embodiments, the first enclosure knockout 263A is not used and a cutout (e.g., the cutout 365 in FIGS. 3A and 7A) in the electronics housing cover is used for input power. In some embodiments, the enclosure 260 includes a second enclosure knockout 263B or opening for a charging cable (e.g., the charging cable 103 in FIG. 1) to connect to the BiDi charger. In some implementations, the second enclosure knockout 263B provides access for the charging cable to an electronic component (e.g., the electronic components 222 in FIGS. 2 and 3B) and/or a field serviceable component (e.g., the field serviceable components 242 in FIGS. 2 and 6). In some implementations, the bottom ribbon 262B includes the first and/or the second enclosure knockout 263A, 263B.

FIG. 10 is a schematic illustration of an enclosure of a BiDi charger (e.g., the BiDi charger 102 in FIGS. 1, 2, and 9-11), in accordance with embodiments of the disclosure.

In some embodiments, the enclosure 260 includes a user interface element 1082 and a light bar assembly 1080. In some embodiments, the user interface element 1082 receives input (e.g., from a user) to control providing power to the vehicle. In some implementation, control circuitry receives the input (e.g., though I/O circuitry) and executes an application to control power based on the input. In some implementations, the user interface element 1082 includes any one or combination of a button, a switch, or a screen.

In some embodiments, the light bar assembly 1080 indicates a status of the BiDi charger 102, which may include any one or combination of a fault status, a charging status, an idle status, or a discharge state status, to name a few examples. In some implementations, the light bar assembly 1080 includes any one or combination of an indicator light, a speaker, an actuator (e.g., for vibration-based or haptic feedback), or a display. In some embodiments, any of the user interface element 1082 or the light bar assembly 1080 are field serviceable.

The accent panel 274 couples to the front cover 266, such as discussed in relation to FIGS. 2 and 10. In some embodiments, the front cover 266 forms a front recess 1067 and the accent panel 274 is arranged in the front recess 1067. The front cover 266 of the enclosure 260 provides access to an internal space (e.g., the internal space 968 in FIG. 9) of the enclosure 260. In some implementations, the front cover 266 is decoupled or removed from the enclosure 260 to provide access. In some implementations, the front cover 266 slides in relation to, or swings away from (e.g., using a hinge) the enclosure 260 to provide access.

In some embodiments, a signal (e.g., the second signal 676B in FIGS. 6A-7B) passes through any of the accent panel 274, the front cover 266, or a service area cover (e.g., the service area housing 240 in FIGS. 2, 6B, 7B, and 9) and is capable of being received at an antenna (e.g., the second antenna 646B in FIGS. 6A and 6B) in the internal space of the enclosure 260. In some embodiments, any of the accent panel 274, the front cover 266, or the service area cover comprises a non-metallic material. In some embodiments, any of the accent panel 274, the front cover 266, or the service area cover do not comprise a metallic material.

FIG. 11 is a schematic illustration of a mounting system 1183 for a BiDi charger (e.g., the BiDi charger 102 in FIGS. 1, 2, and 9-11), in accordance with some embodiments of this disclosure.

In some embodiments, the mounting system includes the mounting cleat 272, a first retention feature 1188, and a mounting bracket 1184. The mounting cleat 272 is coupled to the electronics housing cover 264, which may be used to couple the BiDi charger 102 to the mounting bracket 1184.

The mounting cleat 272 includes first support feature 1186A and a first alignment feature 1186B. The mounting bracket 1184 includes a second support feature 1187A, a second alignment feature 1187B, and a second retention feature 1189. In some embodiments, the mounting bracket 1184 is coupled or attached to an external structure and the mounting cleat 272 and the first retention feature 1188 engages the mounting bracket 1184 to mount the BiDi charger 102 to the external structure. In some implementations, the mounting bracket 1184 is attached to any or a wall, pillar, pole, or column. In some implementations, the mounting bracket is part of a stand or fixture. In some embodiments, any of the first support feature 1186A, second support feature 1187A, first retention feature 1188, or second retention feature 1189 may be considered a mounting feature.

The first alignment feature 1186B engages a second alignment feature 1187B to align the BiDi charger 102 to the mounting bracket 1184. The first support feature 1186A engages the second support feature 1187A to support and retain of the BiDi charger 102 on the mounting bracket 1184. The first retention feature 1188 engages the second retention feature 1189 to retain the BiDi charger 102 on the mounting bracket 1184.

In some embodiments, the first support feature 1186A includes a flange of the mounting cleat 272. The second support feature 1187A includes a channel. The flange contacts the channel to support the BiDi charger 102. In some embodiments, the first alignment feature 1186B includes a first tab extending from the first support feature 1186A. The second alignment feature 1187B includes a slot in the second support feature 1187A. The first tab is placed in the slot to align the BiDi charger 102. In some embodiments, the first retention feature 1188 includes a shaft coupled to a head extending past the shaft exterior. In some implementations, the first retention feature 1188 includes a peg or a shoulder bolt. The second retention 1189 feature includes a groove in a second tab extending from the mounting bracket 1184. The shaft is placed in the groove and the head extends over the second tab to retain the BiDi charger 102.

In the embodiment depicted in FIG. 11, there are two first retention features 1188 and two second retention features 1189. In some embodiments, more or less may be used.

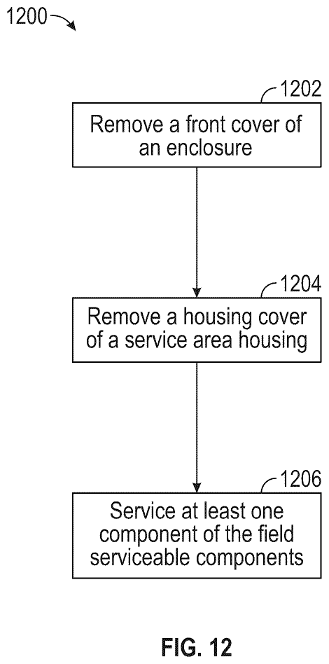

FIG. 12 is a flowchart of an illustrative process 1200 for servicing components (e.g., the field serviceable components 242 in FIGS. 2 and 6) of a BiDi charger (e.g., the BiDi charger 102 in FIGS. 1, 2, and 9-11), in accordance with embodiments of the disclosure.

The process 1200 begins at operation 1202 with removing a front cover (e.g., the front cover 266 in FIGS. 2 and 10) of an enclosure (e.g., the enclosure 260 in FIGS. 2, 9, and 10), such as described above with respect to FIGS. 2 and 10. In some embodiments, the enclosure forms an internal space (e.g., the internal space 968 in FIG. 9).

The process 1200 continues to operation 1204 with removing a housing cover (e.g., the service area cover 256 in FIGS. 2 and 9) of a service area housing (e.g., the service area housing 240 in FIGS. 2, 6B, 7B, and 9), such as described above with respect to FIGS. 2 and 9. In some embodiments, the service area housing is arranged within the internal space. The service area housing comprises field serviceable components (e.g., the field serviceable components 242 in FIGS. 2 and 6) that are accessible when the housing cover is removed.

The process 1200 continues to operation 1206 with servicing at least one component of the field serviceable components, such as described above with respect to FIG. 2. In some embodiments, the servicing includes removing and/or replacing the least one component. In some embodiments, the servicing includes servicing a first component of the field serviceable components that is (i) coupled to the service area housing and (ii) accessible only when the housing cover is removed. The servicing further includes servicing a second component of the field serviceable components that is coupled to the removable side of the enclosure.

FIG. 12 is an illustrative example of a method, and other methods including fewer, additional, or alternative steps are possible consistent with this disclosure. Various modifications can be made to the process 1200 in accordance with various embodiments disclosed herein. In some embodiments, process 1200 is a manual process and at least one of its operations is performed by a user or operator. In some embodiments, process 1200 is an automated process and at least one of its operations is performed using control circuitry.

The foregoing is merely illustrative of the principles of this disclosure and various modifications may be made by those skilled in the art without departing from the scope of this disclosure. The above-described embodiments are presented for purposes of illustration and not of limitation. The present disclosure also can take many forms other than those explicitly described herein. Accordingly, it is emphasized that this disclosure is not limited to the explicitly disclosed methods, systems, and apparatuses, but is intended to include variations to and modifications thereof, which are within the spirit of the following claims.

What is claimed is:

1. An apparatus, comprising:
a body forming a cavity, the body comprising:
a first opening in the body configured to move air into the cavity; and
a second opening in the body configured to move air out of the cavity;
a first heat dissipating structure coupled to a first region of the body, wherein the first heat dissipating structure is configured to remove a first amount of heat;
a first electronic component coupled to a first interior surface of the cavity, wherein:
the first interior surface corresponds to the first region; and
a first heat flow path is formed from the first electronic component, through the first interior surface and the first region, and to the first heat dissipating structure; and
a second heat dissipating structure coupled to a second region of the body, wherein the second heat dissipating structure is configured to remove a second amount of heat.

2. The apparatus of claim 1, further comprising an airflow generating venting device configured to move air out of the second opening.

3. The apparatus of claim 2, wherein the airflow generating venting device is coupled to the body at the second opening.

4. The apparatus of claim 1, wherein:
the cavity comprises a first depth corresponding to the first region and a second depth corresponding to the second region; and
the first depth is deeper than the second depth.

5. The apparatus of claim 4, wherein:
the first region and the second region of the body comprise a respective first exterior surface and second exterior surface of the body;
the first heat dissipating structure comprises first cooling fins extending a first height from the first region;
the second heat dissipating structure comprises second cooling fins extending a second height from the first region;
the first electronic component is coupled to the first interior surface at the first depth of the cavity and opposite the first exterior surface;
the apparatus further comprises
a second electronic component coupled to a second interior surface at the second depth of the cavity and opposite the second exterior surface;
the first heat flow path is further formed through the first exterior surface and to the first cooling fins; and
a second heat flow path is formed from the second electronic component, through the second interior surface and the second exterior surface, and to the second cooling fins.

6. The apparatus of claim 5, wherein the first height of the first cooling fins is shorter than the second height of the second cooling fins.

7. The apparatus of claim 6, wherein:
the first electronic component comprises at least one of a transformer or an inductor; and
the second electronic component comprises a transistor.

8. The apparatus of claim 5, wherein each fin of the first cooling fins and the second cooling fins extends in the same direction.

9. The apparatus of claim 4, further comprising:
a first power circuit board arranged at a third depth less than the second depth; and
a second power circuit board arranged at a fourth depth less than the second depth.

10. The apparatus of claim 9, further comprising:
a first electronic component coupled to (i) a first interior surface of the cavity corresponding to the first exterior surface of the first region and (ii) the first power circuit board; and
a second electronic component coupled to (i) a second interior surface of the cavity corresponding to the second region and (ii) the second power circuit board.

11. The apparatus of claim 9, further comprising:
a power control center circuit board arranged at a fifth depth less than the third and the fourth depths; and
an input filter circuit board arranged at a sixth depth less than the third and the fourth depths.

12. The apparatus of claim 1, further comprising a weather-resistant cover coupled to an exterior of the body at the second opening, wherein when the weather-resistant cover is coupled to the exterior of the body to (i) form a vent for air to exit the cavity through the second opening and the vent and (ii) prevent at least one of rain, moisture, or dust from entering the cavity through the second opening.

13. The apparatus of claim 1, wherein:
the body further comprises a cavity opening for accessing electronic components arranged in the cavity; and
the apparatus further comprises a body cover coupled to the body such that the body cover at least partially covers the cavity opening.

14. The apparatus of claim 13, further comprising an airflow generating stir device arranged in the cavity and configured to move air in the cavity.

15. An apparatus, comprising:
a body forming a cavity, the body comprising a plurality of openings in the body configured to move air through the cavity;
first cooling fins coupled to a first region of the body, each fin of the first cooling fins extending a first height from the first region;
second cooling fins coupled to a second region of the body, each fin of the second cooling fins extending a second height from the second region;
an airflow generating venting device coupled to an opening of the plurality of openings configured to move air out of the opening; and
an airflow generating stir device arranged in the cavity and configured to move air in the cavity.

16. The apparatus of claim 15, wherein:
the cavity comprises a first depth corresponding to the first region and a second depth corresponding to the second region;
the first depth is deeper than the second depth; and
the first height of the first cooling fins is shorter than the second height of the second cooling fins.

17. A method, comprising:
coupling a first electronic component to a first interior surface within a cavity of a housing, wherein:
the housing comprises:
a first heat dissipating structure coupled to a first exterior surface of the housing, wherein the first heat dissipating structure is configured to remove a first amount of heat; and
a second heat dissipating structure coupled to a second exterior surface of the housing, wherein the second heat dissipating structure is configured to remove a second amount of heat; and
the first interior surface is opposite the first exterior surface of the housing; and
coupling a second electronic component to a second interior surface within the cavity of the housing, wherein the second interior surface is opposite the second exterior surface of the housing.

18. The method of claim 17, coupling an airflow generating venting device to the housing at a vent opening, wherein the airflow generating venting device is configured to move air through the vent opening.

19. The method of claim 17, further comprising coupling a housing cover to the housing such that the housing cover at least partially covers an access opening of the housing, wherein the access opening is configured to allow access to the first and the second electronic component within the cavity.

20. The method of claim 17, coupling an airflow generating stir device to a third interior surface within the cavity, wherein the airflow generating stir device is configured to move air in the cavity.
